(19) United States
(12) Patent Application Publication
(10) Pub. No.: US 2025/0201735 A1
(43) Pub. Date: Jun. 19, 2025

(54) OPTICAL SEMICONDUCTOR DEVICE AND METHOD FOR MANUFACTURING OPTICAL SEMICONDUCTOR DEVICE

(71) Applicant: SUMITOMO ELECTRIC INDUSTRIES, LTD., Osaka (JP)

(72) Inventors: Munetaka KUROKAWA, Osaka (JP); Katsumi UESAKA, Osaka (JP); Hiroshi UEMURA, Osaka (JP)

(73) Assignee: SUMITOMO ELECTRIC INDUSTRIES, LTD., Osaka (JP)

(21) Appl. No.: 18/975,481

(22) Filed: Dec. 10, 2024

(30) Foreign Application Priority Data
Dec. 15, 2023 (JP) 2023-212257
Dec. 6, 2024 (JP) 2024-213192

(51) Int. Cl. H01L 23/00; H01L 21/02; H01L 25/16

(52) U.S. Cl. CPC H01L 23/564; H01L 21/02126; H01L 24/29; H01L 24/32; H01L 25/167; H01L 2224/29023; H01L 2224/32111; H01L 2924/19011

(57) ABSTRACT

An optical semiconductor device according to an embodiment includes: a first semiconductor element having a first bonding surface and an end surface which crosses the first bonding surface and from which an optical signal is emitted; and a second semiconductor element having a second bonding surface facing the first bonding surface and an optical waveguide which extends in a direction parallel to the second bonding surface and through which the optical signal is transmitted. The first bonding surface and the second bonding surface are bonded to each other in a hydrophilic manner, and the end surface of the first semiconductor element and the optical waveguide of the second semiconductor element are optically coupled to each other.

### CROSS-REFERENCE TO RELATED APPLICATION

This application claims priority from Japanese Patent Application No. 2023-212257, filed on Dec. 15, 2023, the entire subject matter of which is incorporated herein by reference.

### TECHNICAL FIELD

The present disclosure relates to an optical semiconductor device and a method for manufacturing an optical semiconductor device.

### BACKGROUND

Japanese Unexamined Patent Publication No. 2022-132130 describes a semiconductor light emitting device and a method for manufacturing the same. The semiconductor light emitting device includes a first n-side nitride semiconductor layer, a first active layer provided on the first n-side nitride semiconductor layer, a first light emitting portion containing at least a first p-side nitride provided on the first active layer, and a second n-side nitride semiconductor layer directly bonded to the first light emitting portion. The first light emitting portion has a first bonding surface, and the second n-side nitride semiconductor layer has a second bonding surface. The first bonding surface is directly bonded to the second bonding surface. The first bonding surface is in direct contact with the second bonding surface without using a resin, an adhesive, and the like. As direct contact, bonding by direct contact using a surface activated bonding method, an atomic diffusion bonding method, and the like is described.

International Publication WO 2015/146377 describes an optical module. The optical module is an integrated laser module in which an LD element, a driver 1C, an optical fiber, and a sub-substrate are mounted on the top surface of an Si platform, which is a substrate formed of silicon. A driver IC is mounted on the LD element by soldering. The LD element with the driver IC mounted thereon is mounted on the top surface of the Si platform by surface activated bonding. The Si platform has a bonding portion to which the sub-substrate and the LD element are bonded. The sub-substrate and the LD element are each bonded onto the bonding portion of the Si platform by surface activated bonding.

Japanese Unexamined Patent Publication No. 2013-228691 describes an optical module in which a wavelength conversion element, which is an optical element, is mounted on a silicon substrate. The silicon substrate has a bonding portion that is a micro-bump structure formed of gold. The wavelength conversion element is bonded to the bonding portion using a surface activated bonding technique.

Specification of U.S. Patent Application Publication No. 2022/0123518 describes a laser chip having a light source that is flip-chip mounted on a silicon photonics chip having an optical waveguide. The silicon photonics chip and the laser chip each have a vertical stopper. The alignment of the laser chip with respect to the silicon photonics chip is performed by butting two vertical stoppers up and down against each other. The laser chip is mounted on the silicon photonics chip using a solder.

### SUMMARY

An optical semiconductor device according to the present disclosure includes: a first semiconductor element having a first bonding surface and an end surface which crosses the first bonding surface and from which an optical signal is emitted; and a second semiconductor element having a second bonding surface facing the first bonding surface and an optical waveguide which extends in a direction parallel to the second bonding surface and through which the optical signal is transmitted. The first bonding surface and the second bonding surface are bonded to each other in a hydrophilic manner, and the end surface of the first semiconductor element and the optical waveguide of the second semiconductor element are optically coupled to each other.

### BRIEF DESCRIPTION OF THE DRAWINGS

FIG. 1 is a perspective view showing an optical semiconductor device according to a first embodiment.

FIG. 2 is a cross-sectional view of an optical semiconductor device taken along a plane perpendicular to the optical waveguide of a second semiconductor element of the optical semiconductor device in FIG. 1.

FIG. 3 is a drawing schematically showing a cross section of a first semiconductor element in the optical semiconductor device in FIG. 2.

FIG. 4 is a drawing showing a first modification example of the cross section of the first semiconductor element in FIG. 3.

FIG. 5 is a drawing showing a second modification example of the cross section of the first semiconductor element in FIG. 3.

FIG. 6 is a drawing showing a third modification example of the cross section of the first semiconductor element in FIG. 3.

FIG. 7 is a drawing showing a fourth modification example of the cross section of the first semiconductor element in FIG. 3.

FIG. 8 is a drawing showing a fifth modification example of the cross section of the first semiconductor element in FIG. 3.

FIG. 9 is a drawing for explaining a hydrophilic treatment performed on a first semiconductor element and a second semiconductor element.

FIG. 10 is a drawing for explaining a hydrophilic treatment, temporary bonding, and main bonding in a method for manufacturing an optical semiconductor device according to the first embodiment.

FIG. 11 is a drawing showing steps of the method for manufacturing an optical semiconductor device according to the first embodiment.

FIG. 12 is a perspective view showing an optical semiconductor device according to a second embodiment.

FIG. 13 is a cross-sectional view of an optical semiconductor device taken along a plane perpendicular to the optical waveguide of a second semiconductor element of the optical semiconductor device in FIG. 12.

FIG. 14 is a drawing schematically showing a cross section of a first semiconductor element in the optical semiconductor device in FIG. 13.

FIG. 15 is a drawing schematically showing a cross section of a modification example of the first semiconductor element in FIG. 14.

FIG. 16 is a drawing showing a modification example of the cross section of the first semiconductor element in FIG. 15.

FIG. 17 is a drawing showing a modification example of a cross section of the first semiconductor element in FIG. 15, which is different from that in FIG. 16.

FIG. 18 is a drawing showing steps of a method for manufacturing an optical semiconductor device according to the second embodiment.

FIG. 19 is a drawing showing steps of a method for manufacturing an optical semiconductor device according to a third embodiment.

FIG. 20 is a drawing showing an optical semiconductor device according to the third embodiment.

FIG. 21 is a drawing showing steps of a method for manufacturing an optical semiconductor device according to a fourth embodiment.

FIG. 22 is a drawing showing steps of a method for manufacturing an optical semiconductor device according to a fifth embodiment.

FIG. 23 is a perspective view showing an optical semiconductor device according to a sixth embodiment.

FIG. 24 is an enlarged perspective view of a first bonding agent layer and a second bonding agent layer of the optical semiconductor device in FIG. 23.

FIG. 25 is a perspective view showing a second semiconductor element of the optical semiconductor device in FIG. 23.

FIG. 26 is an enlarged cross-sectional view of a portion of the second semiconductor element in FIG. 25.

FIG. 27 is an enlarged cross-sectional view of a portion of the second semiconductor element in FIG. 25.

FIG. 28 is a cross-sectional view showing the optical semiconductor device of FIG. 23 before and after solder melting.

FIG. 29 is a cross-sectional view showing the optical semiconductor device of FIG. 23 before and after solder melting.

FIG. 30 is a drawing showing steps of a method for manufacturing an optical semiconductor device according to a sixth embodiment.

FIG. 31 is a perspective view showing an optical semiconductor device according to a seventh embodiment.

FIG. 32 is a perspective view showing a second semiconductor element of the optical semiconductor device in FIG. 31.

FIG. 33 is a cross-sectional view of the second semiconductor element in FIG. 32.

FIG. 34 is an enlarged cross-sectional view of a portion of the optical semiconductor device shown in FIG. 31.

FIG. 35 is a cross-sectional view showing the optical semiconductor device of FIG. 31 before and after solder melting.

### DETAILED DESCRIPTION

As described above, when mounting the laser chip on the silicon photonics chip using a solder, the solder is heated after the alignment of the laser chip with respect to the silicon photonics chip. When this heating is performed, the laser chip may be misaligned. If the laser chip is misaligned, the efficiency of optical coupling may be lowered. Therefore, there is a demand for highly accurate mounting by suppressing misalignment.

It is an object of the present disclosure to provide an optical semiconductor device, in which mounting can be performed with high accuracy by suppressing misalignment, and a method for manufacturing the optical semiconductor device.

According to the present disclosure, mounting can be performed with high accuracy by suppressing misalignment.

### Description of Embodiment of Present Disclosure

First, the contents of embodiments of the present disclosure will be listed and described. (1) An optical semiconductor device according to an embodiment includes: a first semiconductor element having a first bonding surface and an end surface which crosses the first bonding surface and from which an optical signal is emitted; and a second semiconductor element having a second bonding surface facing the first bonding surface and an optical waveguide which extends in a direction parallel to the second bonding surface and through which the optical signal is transmitted. The first bonding surface and the second bonding surface are bonded to each other in a hydrophilic manner, and the end surface of the first semiconductor element and the optical waveguide of the second semiconductor element are optically coupled to each other.

In the optical semiconductor device and the method for manufacturing an optical semiconductor device, the first semiconductor element has the first bonding surface and the end surface, and the second semiconductor element has the second bonding surface and the optical waveguide. The end surface of the first semiconductor element and the optical waveguide of the second semiconductor element are optically coupled to each other, and the first bonding surface and the second bonding surface are bonded to each other in a hydrophilic manner. Hydrophilic bonding does not require heating after the alignment of the first bonding surface with respect to the second bonding surface. Therefore, it is possible to suppress the misalignment of the first semiconductor element with respect to the second semiconductor element due to heating. As a result, the mounting of the first semiconductor element with respect to the second semiconductor element can be performed with high accuracy by suppressing misalignment.

(2) In the above (1), an oxide film may be formed at a bonded portion that is a portion where the first bonding surface and the second bonding surface are bonded to each other in a hydrophilic manner. In this case, the first bonding surface can be firmly bonded to the second bonding surface by the oxygen atoms forming the oxide film.

(3) In the above (1) or (2), the first semiconductor element may have a third bonding surface parallel to the first bonding surface, and the second semiconductor element may have a fourth bonding surface facing the third bonding surface. The third bonding surface and the fourth bonding surface are bonded to each other at the bonded portion by a bonding agent. The bonded portion is formed in the overlapping region between the third bonding surface and the fourth bonding surface when viewed along the crossing direction, which is a direction crossing the third bonding surface. The optical semiconductor device may further include a bonding agent layer formed on at least one of the third bonding surface and the fourth bonding surface. The bonding agent layer is formed of a bonding agent. At the bonded portion, the bonding agent layer is filled between the third bonding surface and the fourth bonding surface. The area of the bonding agent layer when viewed along the crossing direction may be larger than the area of the bonded portion when viewed along the crossing direction. In addition to the bonding agent layer being filled between the third bonding surface and the fourth bonding surface at the bonded portion, since the area of the bonding agent layer is larger than the area of the bonded portion, a reliable bond between the third bonding surface and the fourth bonding surface at the bonded portion is ensured. The area of the bonding agent layer is, for example, equal to or less than the area of the fourth bonding surface.

(4) In the above (1) or (2), the second bonding surface may have a first small bonding surface and a second small bonding surface spaced apart from each other along a first direction, which is a direction parallel to the second bonding surface. The first semiconductor element may have, between the first small bonding surface and the second small bonding surface, a third bonding surface being parallel to the first bonding surface and extending in a second direction, which is a direction crossing the first direction. The second semiconductor element may have a fourth bonding surface facing the third bonding surface and extending in the first direction. The third bonding surface and the fourth bonding surface are bonded to each other at the bonded portion by a bonding agent. The bonded portion is formed in the overlapping region between the third bonding surface and the fourth bonding surface when viewed along the crossing direction. The optical semiconductor device may further include a bonding agent layer formed on at least one of the third bonding surface and the fourth bonding surface. The bonding agent layer is composed of a bonding agent. At the bonded portion, the bonding agent layer is filled between the third bonding surface and the fourth bonding surface. The area of the bonding agent layer when viewed along the crossing direction, which is a direction crossing the third bonding surface, may be larger than the area of the bonded portion when viewed along the crossing direction. In addition to the bonding agent layer being filled between the third bonding surface and the fourth bonding surface at the bonded portion, since the area of the bonding agent layer is larger than the area of the bonded portion, a reliable bond between the third bonding layer and the fourth bonding layer at the bonded portion is ensured. When the bonding agent layer is formed on the third bonding layer, the area of the bonding agent layer is equal to or less than the area of the third bonding layer, and when the bonding agent layer is formed on the fourth bonding layer, the area of the bonding agent layer is equal to or less than the area of the fourth bonding layer.

(5) A method for manufacturing an optical semiconductor device according to an embodiment includes: a step of making a first bonding surface of a first semiconductor element hydrophilic; a step of aligning an end surface of the first semiconductor element, from which an optical signal is emitted, and an optical waveguide of a second semiconductor element, through which the optical signal is transmitted, so as to be optically coupled to each other by making the first bonding surface face a second bonding surface of the second semiconductor element with the first bonding surface spaced apart from the second bonding surface; a step of temporarily bonding the first semiconductor element and the second semiconductor element to each other by bringing the first bonding surface into contact with the second bonding surface at a first temperature and pressing at least one of the first semiconductor element and the second semiconductor element; and a step of heating the first semiconductor element and the second semiconductor element after the temporary bonding step for main bonding between the first bonding surface and the second bonding surface at a second temperature higher than the first temperature.

(6) In the above (5), in the hydrophilizing step, the first bonding surface may be made hydrophilic by irradiating the first bonding surface with ultraviolet light in an air exposure environment. In this case, damage to the first bonding surface can be suppressed when the first bonding surface is made hydrophilic. This reduces the deterioration of hydrophilic bonding caused by the roughening of the first bonding surface.

(7) In the above (5), in the hydrophilizing step, the first bonding surface may be made hydrophilic by exposing the first bonding surface to oxygen plasma in a vacuum environment. In this case, when the first bonding surface is made hydrophilic, a thick oxide film can be formed on the first bonding surface. The bonding strength can be enhanced by a thick oxide film.

(8) In the above (5), in the hydrophilizing step, the first bonding surface may be made hydrophilic by exposing the first bonding surface to nitrogen plasma in a vacuum environment.

(9) In any of the above (5) to (8), a strength of a bonded portion, which is a portion where the first bonding surface and the second bonding surface are bonded to each other, after the temporary bonding step may be 5 MPa or more. In this case, the first semiconductor element can be firmly bonded to the second semiconductor element in the temporary bonding.

(10) In any of the above (5) to (9), a distance between the first bonding surface and the second bonding surface when performing the alignment step may be 1 μm or more and less than 100 μm. In this case, since the distance between the first bonding surface and the second bonding surface during alignment can be reduced, misalignment of the first bonding surface with respect to the second bonding surface can be more reliably suppressed.

(11) In any of the above (5) to (10), the first temperature may be 20° C. or more and 40° C. or less, and the second temperature may be 100° C. or more and 300° C. or less. In this case, since the first temperature during the temporary bonding can be room temperature, misalignment due to heating can be more reliably suppressed.

(12) In any of the above (5) to (11), the first semiconductor element may have a third bonding surface parallel to the first bonding surface, and the second semiconductor element may have a fourth bonding surface facing the third bonding surface. The method for manufacturing may include a step of forming a first bonding agent layer formed of an electrical bonding agent on the fourth bonding surface and forming a second bonding agent layer formed of an electrical bonding agent on the first bonding agent layer before the alignment step. The method for manufacturing may include a step of melting the first bonding agent layer and the second bonding agent layer through heating, and bonding the third bonding surface and the fourth bonding surface to each other at the bonded portion by the bonding agent layer, which is the melted first bonding agent layer and the melted second bonding agent layer. In this case, the bonding agent layer, which is the melted first bonding agent layer and the melted second bonding agent layer, is filled the gap between the third bonding layer and the fourth bonding layer at the bonded portion, thereby ensuring a reliable bond between the third bonding surface and the fourth bonding surface at the bonded portion.

### Details of Embodiment of Present Disclosure

Hereinafter, specific examples of an optical semiconductor device and a method for manufacturing an optical semiconductor device according to embodiments of the present disclosure will be described with reference to the accompanying drawings. In addition, the present disclosure is not limited to the following examples, and is indicated by the appended claims and is intended to include all modifications within the scope of the claims and equivalents thereto. In the description of the drawings, the same or equivalent elements are denoted by the same reference numerals, and repeated description thereof will be omitted. For ease of understanding, parts of the drawings may be simplified or exaggerated, and the dimensional ratios and the like are not limited to those described in the drawings.

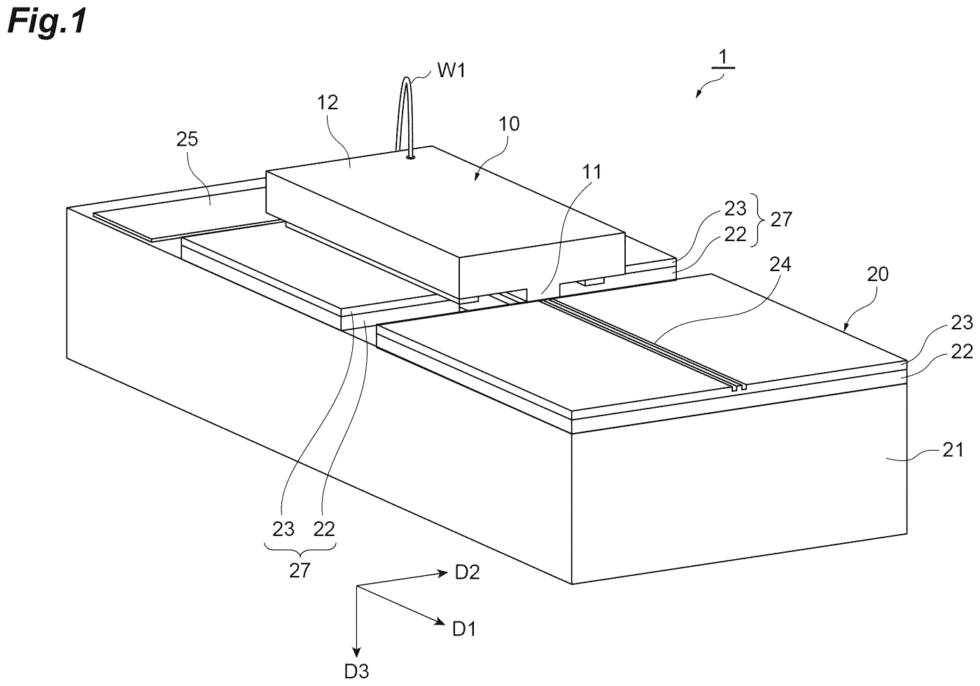

FIG. 1 is a perspective view showing an optical semiconductor device 1 according to the present embodiment. As shown in FIG. 1, the optical semiconductor device 1 has a rectangular parallelepiped shape. The optical semiconductor device 1 includes a first semiconductor element 10 and a second semiconductor element 20. For example, the second semiconductor element 20 is a silicon photonics chip, and the first semiconductor element 10 is an optical semiconductor element fixed to the second semiconductor element 20. The optical semiconductor element is, for example, a semiconductor laser element or a semiconductor optical amplifier element. The semiconductor laser element and the semiconductor optical amplifier element serve as a light source to supply light to the silicon photonics chip. Hereinafter, a direction in which the first semiconductor element 10 is provided when viewed from the second semiconductor element 20 may be referred to as top, upper side, or upward, and the opposite direction may be referred to as bottom, lower side, or downward. However, these directions are for convenience of explanation and do not limit the arrangement position, direction, and the like of an object.

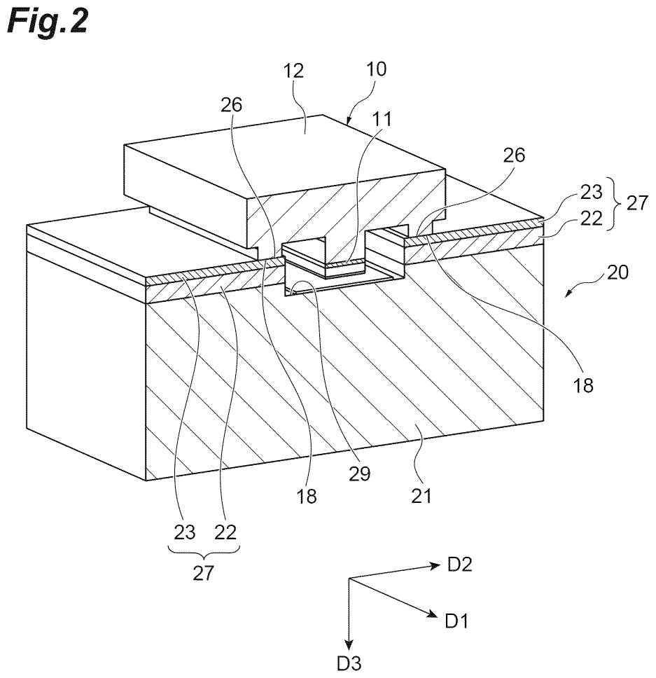

For example, the second semiconductor element 20 has a rectangular parallelepiped shape. FIG. 2 is a cross-sectional view of the first semiconductor element 10 and the second semiconductor element 20 taken along a plane extending in both the up-down direction and the width direction of the second semiconductor element 20. As shown in FIGS. 1 and 2, the first semiconductor element 10 has an end surface 11 from which an optical signal can be emitted. The second semiconductor element 20 has an optical waveguide 24 capable of transmitting an optical signal. The end surface 11 and the optical waveguide 24 are optically coupled to each other.

For example, the second semiconductor element 20 has a first layer 21, a second layer 22 located on the first layer 21, and a third layer 23 located on the second layer 22. The first layer 21 is, for example, a silicon (Si) layer. The first layer 21 has a rectangular parallelepiped shape. The second semiconductor element 20 has, for example, a plurality of second layers 22 and a plurality of third layers 23. The second layer 22 extends along a first direction D1, which is a direction in which the optical waveguide 24 extends, and a second direction D2, which will be described later. In addition, the third layer 23 extends along the first direction D1 and the second direction D2. The two second layers 22 are spaced apart from each other along the first direction D1, which is a direction in which the optical waveguide 24 is provided when viewed from the end surface 11. The two third layers 23 are spaced apart from each other along the first direction D1. Here, the optical waveguide 24 is formed in one of the third layers 23, and the optical waveguide 24 is not formed in the other third layer 23. One second layer 22 is located below one third layer 23, and the other second layer 22 is located below the other third layer 23. In addition, the two second layers 22 spaced apart from each other along the first direction D1 may be integrated with each other. The two third layers 23 spaced apart along the first direction D1 may be integrated with each other.

Among the plurality of second layers 22, two second layers 22 in which the optical waveguide 24 is not formed are spaced apart from each other along the second direction D2, which is a direction crossing (for example, perpendicular to) the first direction D1. Among the plurality of third layers 23, two third layers 23 in which the optical waveguide 24 is not formed are spaced apart from each other along the second direction D2. Each of the two third layers 23 and the two second layers 22 aligned along the second direction D2 has a second bonding surface 26 facing a first bonding surface 18, which will be described later, of the first semiconductor element 10. The optical waveguide 24 extends in a direction parallel to the second bonding surface 26. Each of the two third layers 23 and the two second layers 22 aligned along the second direction D2 is, for example, a support portion 27 that supports the first semiconductor element 10. The second semiconductor element 20 has the second bonding surface 26 located on the third layer 23 of the support portion 27. The second layer 22 is also referred to as a BOX layer. As an example, the length of the support portion 27 in the second direction D2 is 0.03 mm or more. As an example, the length of the support portion 27 in a third direction D3 is set to a length that allows a mesa, which will be described later, of the first semiconductor element 10 to fit between the two third layers 23 aligned along the second direction D2.

When viewed from above (in plan view), the third layer 23 has a rectangular shape. The third layer 23, the second layer 22, and the first layer 21 are aligned in this order along the third direction D3 crossing both the first direction D1 and the second direction D2. The third direction D3 is, for example, vertically downward. The second layer 22 has a rectangular shape. The third layer 23 may have the same shape as the second layer 22 in plan view. Therefore, the third layer 23 may overlap the second layer 22 in plan view. For example, the second layer 22 is an SiO₂ layer, and the third layer 23 is an Si layer. The optical waveguide 24 extends along the first direction D1 in the third layer 23.

The second semiconductor element 20 has, for example, an electrode 25 provided on the first layer 21. The electrode 25 is formed of, for example, gold (Au). The electrode 25 is located, for example, on a side opposite to the optical waveguide 24 when viewed from the first semiconductor element 10. The first semiconductor element 10 has an electrode 12 that forms a surface of the first semiconductor element 10 facing upward. The electrode 25 is electrically connected to the electrode 12 through, for example, a bonding wire W1. For example, the bonding wire W1 is formed of Au.

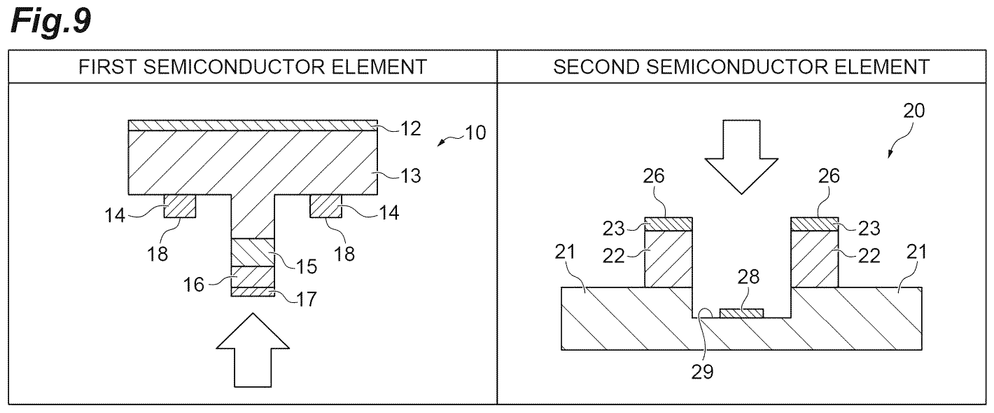

The second semiconductor element 20 has a recessed portion 29 that is recessed in the third direction D3 between the two second layers 22 aligned along the second direction D2. The length (depth) of the recessed portion 29 in the third direction D3 is, for example, 20 μm or less. In addition, the second semiconductor element 20 may not have the recessed portion 29. The second semiconductor element 20 has, for example, an electrode 28 (see FIG. 9) provided on the recessed portion 29 between the two second layers 22 aligned along the second direction D2. The electrode 28 is formed of, for example, Au.

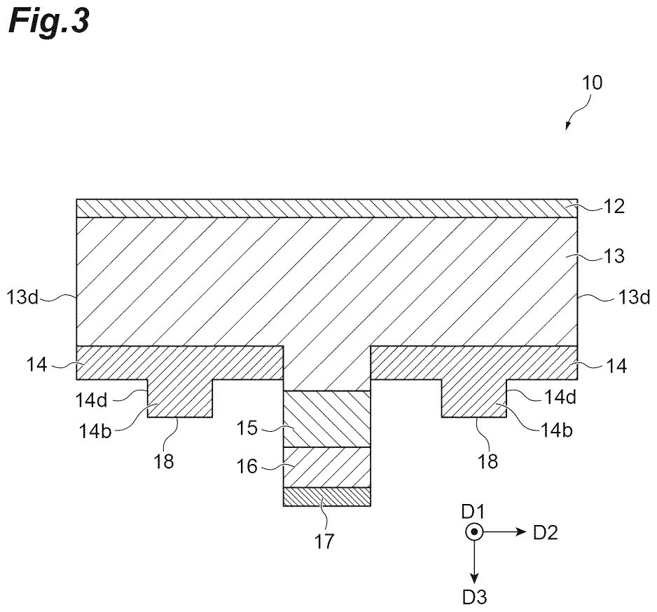

The first semiconductor element 10 is mounted on one of the plurality of third layers 23 in which the optical waveguide 24 is not formed. FIG. 3 is a drawing schematically showing a cross section of the first semiconductor element 10 in FIG. 2. As shown in FIGS. 2 and 3, the first semiconductor element 10 has the above-described electrode 12, an n-InPlayer 13, a p-InP layer 14, an MQW layer 15, a p-InP layer 16, and an electrode 17.

The electrodes 12 and 17 are formed of, for example, gold (Au). The MQW layer 15 includes, for example, a quantum well structure MQW (multi quantum well). The MQW layer 15 emits an optical signal. The MQW layer 15 is formed of, for example, gallium indium arsenide (GaInAs) or gallium indium arsenide phosphide (GaInAsP). The MQW layer 15 may contain other compound semiconductor materials. The MQW layer 15 and the p-InP layer 16 are formed in a mesa shape on the n-InP layer 13. The p-InP layer 14 has a protruding portion 14b that protrudes in the third direction D3. A surface 14d of the protruding portion 14b opposite to the mesa is located closer to the center of the first semiconductor element 10 in the second direction D2 than a surface 13d of the n-InP layer 13 opposite to the mesa.

For example, the length of the first semiconductor element 10 in the first direction D1 is 0.5 mm or more, the length of the first semiconductor element 10 in the second direction D2 is 0.2 mm or more and 0.5 mm or less, and the length of the first semiconductor element 10 in the third direction D3 is 0.05 mm or more. The first semiconductor element 10 has the first bonding surface 18 that is a surface to be bonded to the second semiconductor element 20. The end surface 11 crosses the first bonding surface 18. The first bonding surface 18 extends in both the first direction D1 and the second direction D2 at the end of the protruding portion 14b in the third direction D3. The first bonding surface 18 is formed in the p-InPlayer 14, for example. The first semiconductor element 10 has a plurality of (for example, two) first bonding surfaces 18 (protruding portions 14b). The plurality of first bonding surfaces 18 are aligned along the second direction D2.

The first bonding surface 18 is formed, for example, by dry etching, wet etching, or epitaxial growth of the p-InP layer 14. Therefore, the first bonding surface 18 has good flatness, and accordingly, is suitable for hydrophilic bonding, which will be described later. As an example, the surface roughness of the first bonding surface 18 is several tens of nm or less. The surface roughness (Ra) of the first bonding surface 18 may be 5 nm or less. The position of the first bonding surface 18 in the third direction D3 is adjusted so that the position of the optical axis of the optical signal emitted from the MQW layer 15 matches the position of the optical waveguide 24.

For example, the length of the first bonding surface 18 in the second direction D2 is smaller than the length of the support portion 27 in the second direction D2. However, the length of the first bonding surface 18 in the second direction D2 may be larger than the length of the support portion 27 in the second direction D2. The first semiconductor element 10 moves in the second direction D2 when aligned. For example, when the length of the support portion 27 in the second direction D2 is equal to or greater than the amount of the alignment allowance, the bonding area of the first bonding surface 18 with respect to the second bonding surface 26 is more reliably ensured.

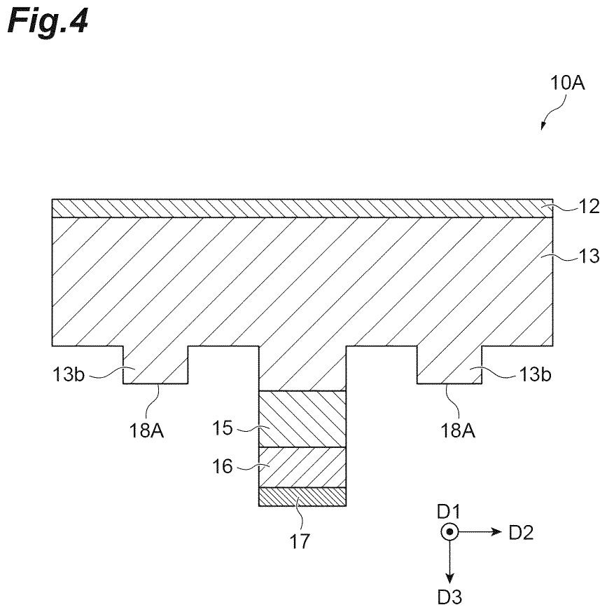

Up to now, the first semiconductor element 10 has been described. However, the configuration of the first semiconductor element is not limited to the first semiconductor element 10 described above. FIG. 4 is a drawing schematically showing a cross section of a first semiconductor element 10A according to a first modification example. Hereinafter, a modification example of the optical semiconductor device will be described. The configuration of a part of an optical semiconductor device according to the modification example is the same as the configuration of a part of the optical semiconductor device 1 described above. Therefore, in the following explanations, those overlapping the explanations of the optical semiconductor device 1 described above will be omitted as appropriate by assigning the same reference numerals.

The first semiconductor element 10A has an electrode 12, an n-InP layer 13, an MQW layer 15, a p-InP layer 16, and an electrode 17, but does not have the p-InP layer 14. The n-InP layer 13 has a protruding portion 13b that protrudes in the third direction D3. The first semiconductor element 10A has a first bonding surface 18A, and the first bonding surface 18A is formed on the n-InP layer 13. The first bonding surface 18A extends in both the first direction D1 and the second direction D2 at the end of the protruding portion 13b in the third direction D3. For example, the shape, size, and number of the first bonding surface 18A are the same as the shape, size, and number of the first bonding surface 18 described above. The first bonding surface 18A is an interface between the n-InP layer 13 and the MQW layer 15. The first bonding surface 18A is formed by dry etching, wet etching, or epitaxial growth of the n-InP layer 13. Therefore, the first bonding surface 18A has good flatness, and accordingly, is suitable for hydrophilic bonding.

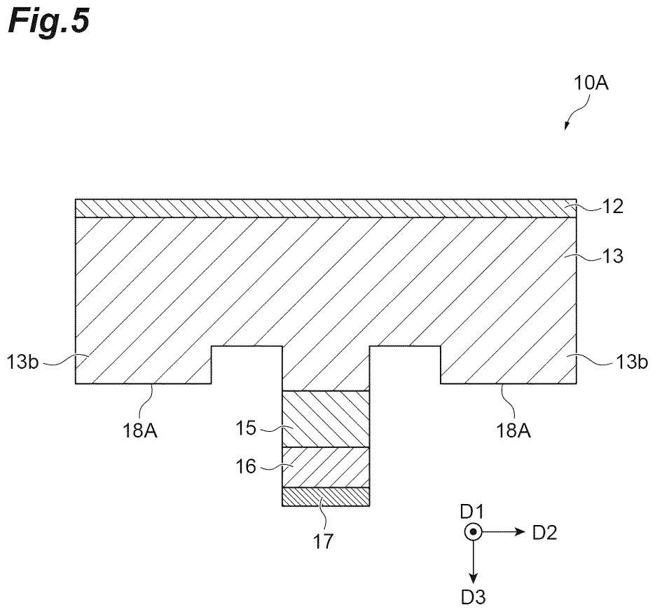

FIG. 5 is a drawing schematically showing a cross section of a first semiconductor element 10A according to a second modification example. In the first semiconductor element 10A according to the second modification example, the end of the first bonding surface 18A in the second direction D2 on a side opposite to the mesa is aligned along the third direction D3 with a surface of the n-InP layer 13 opposite to the mesa. That is, the end of the first bonding surface 18A opposite to the mesa reaches the end of the n-InP layer 13 opposite to the mesa. Therefore, in the second modification example, the area of the first bonding surface 18A can be made larger than that in the first modification example.

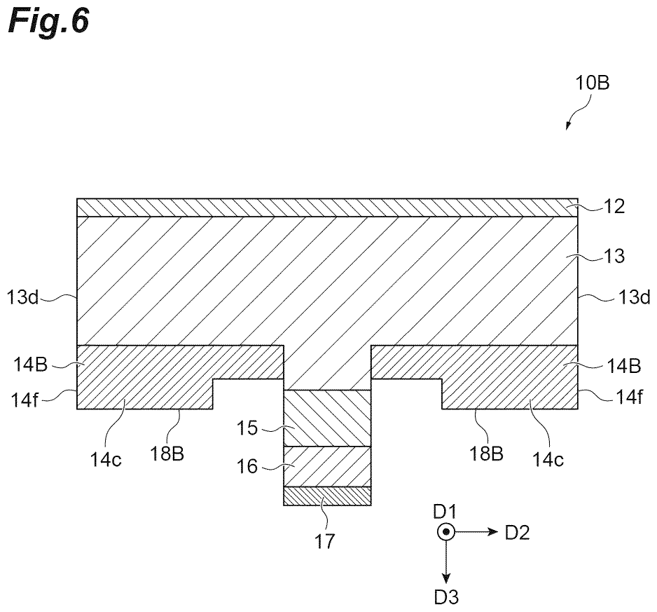

FIG. 6 is a drawing schematically showing a cross section of a first semiconductor element 10B according to a third modification example. The first semiconductor element 10B includes a p-InP layer 14B having a different shape than the p-InP layer 14. The p-InP layer 14B has a protruding portion 14c that is different in size from the protruding portion 14b described above. A surface 14f of the protruding portion 14c opposite to the mesa is aligned along the third direction D3 with a surface 13d of the n-InP layer 13 opposite to the mesa. The first semiconductor element 10B has a first bonding surface 18B. The end of the first bonding surface 18B in the second direction D2 on a side opposite to the mesa is aligned along the third direction D3 with the end of the n-InP layer 13 in the second direction D2. Since the first bonding surface 18B can be formed in the same manner as the first bonding surface 18, the first bonding surface 18B has good flatness. Therefore, the first bonding surface 18B is suitable for hydrophilic bonding.

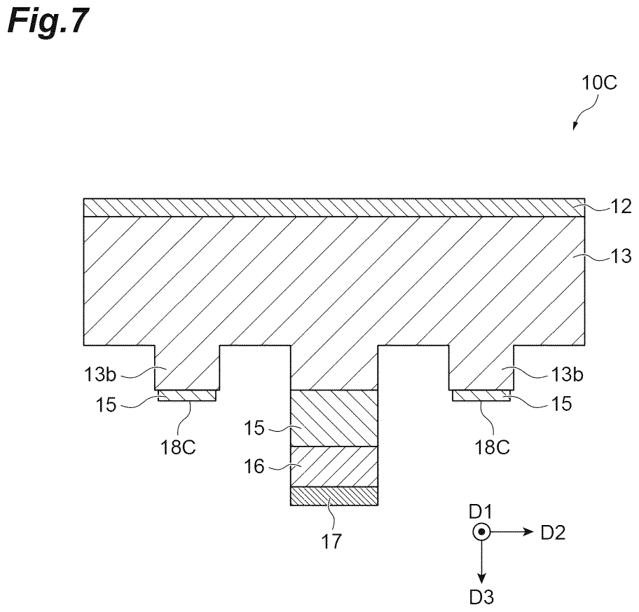

FIG. 7 is a drawing schematically showing a cross section of a first semiconductor element 10C according to a fourth modification example. The first semiconductor element 10C has an electrode 12, an n-InPlayer 13, an MQW layer 15, a p-InP layer 16, and an electrode 17. The n-InPlayer 13 has a protruding portion 13b, and the MQW layer 15 is formed at the end of the protruding portion 13b in the third direction D3. The first semiconductor element 10C has a first bonding surface 18C, and the first bonding surface 18C is formed on the MQW layer 15. The first bonding surface 18C extends in both the first direction D1 and the second direction D2 at the end of the MQW layer 15 in the third direction D3 formed on the protruding portion 13b. Since the first bonding surface 18C can be formed in the same manner as the first bonding surface 18, the first bonding surface 18C has good flatness. Therefore, the first bonding surface 18C is suitable for hydrophilic bonding.

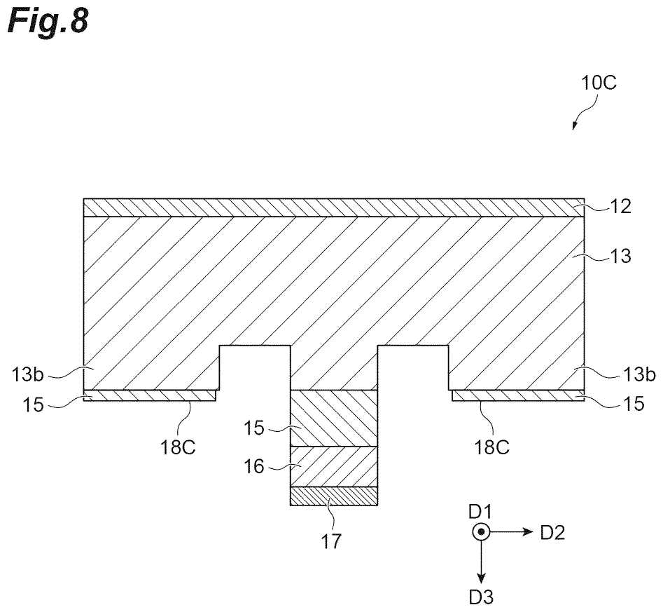

FIG. 8 is a drawing schematically showing a cross section of a first semiconductor element 10C according to a fifth modification example. In the first semiconductor element 10C according to the fifth modification example, the end of the first bonding surface 18C opposite to the mesa is aligned along the third direction D3 with a surface of the n-InP layer 13 opposite to the mesa. That is, the end of the first bonding surface 18C opposite to the mesa reaches the end of the n-InP layer 13 opposite to the mesa. Therefore, in the fifth modification example, the area of the first bonding surface 18C can be made larger than that in the fourth modification example.

Next, a method for manufacturing an optical semiconductor device according to the present embodiment will be described. A method for manufacturing the above-described optical semiconductor device 1 will be described below. First, as shown in FIG. 9, the first semiconductor element 10 and the second semiconductor element 20 are prepared. The first semiconductor element 10 has the flat first bonding surface 18. The second semiconductor element 20 has the flat second bonding surface 26. As an example, the surface roughness of the first bonding surface 18 is several tens of nm or less. The surface roughness (Ra) of the first bonding surface 18 may be 5 nm or less. As an example, the surface roughness of the second bonding surface 26 is several tens of nm or less. The surface roughness (Ra) of the second bonding surface 26 may be 5 nm or less. Then, the first bonding surface 18 of the first semiconductor element 10 is made hydrophilic (a step of making the first bonding surface hydrophilic). At this time, the second bonding surface 26 of the second semiconductor element 20 may be made hydrophilic. “Making the bonding surface hydrophilic” refers to, for example, forming a hydroxyl group or a silanol group on the bonding surface. Hereinafter, making the surface hydrophilic may be referred to as a hydrophilic treatment.

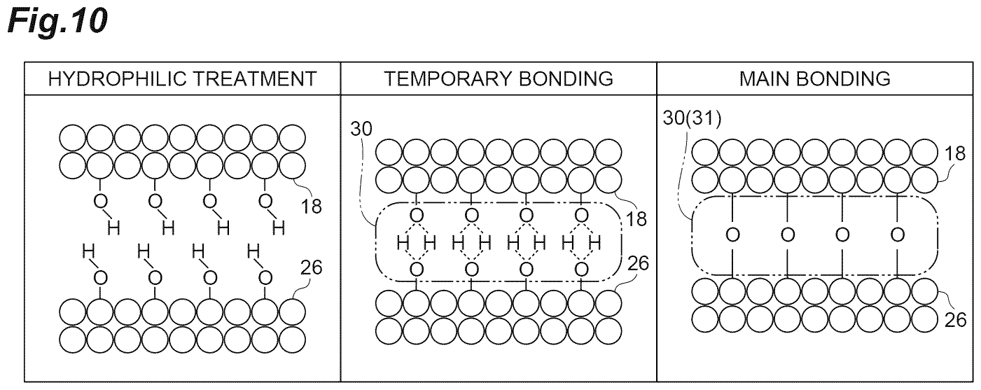

For example, as shown in FIG. 10, by performing a hydrophilic treatment on the first bonding surface 18 and the second bonding surface 26, OH groups are formed on each of the first bonding surface 18 and the second bonding surface 26. In the hydrophilic treatment, for example, the first bonding surface 18 is irradiated with ultraviolet light in an air exposure environment to make the first bonding surface 18 hydrophilic. In the hydrophilic treatment, the first bonding surface 18 may be made hydrophilic by exposing the first bonding surface 18 to oxygen plasma in a vacuum environment. In addition, in the hydrophilic treatment, the first bonding surface 18 may be made hydrophilic by exposing the first bonding surface 18 to nitrogen plasma in a vacuum environment. For example, the hydrophilic treatment for the second bonding surface 26 may be performed in the same manner as the hydrophilic treatment for the first bonding surface 18.

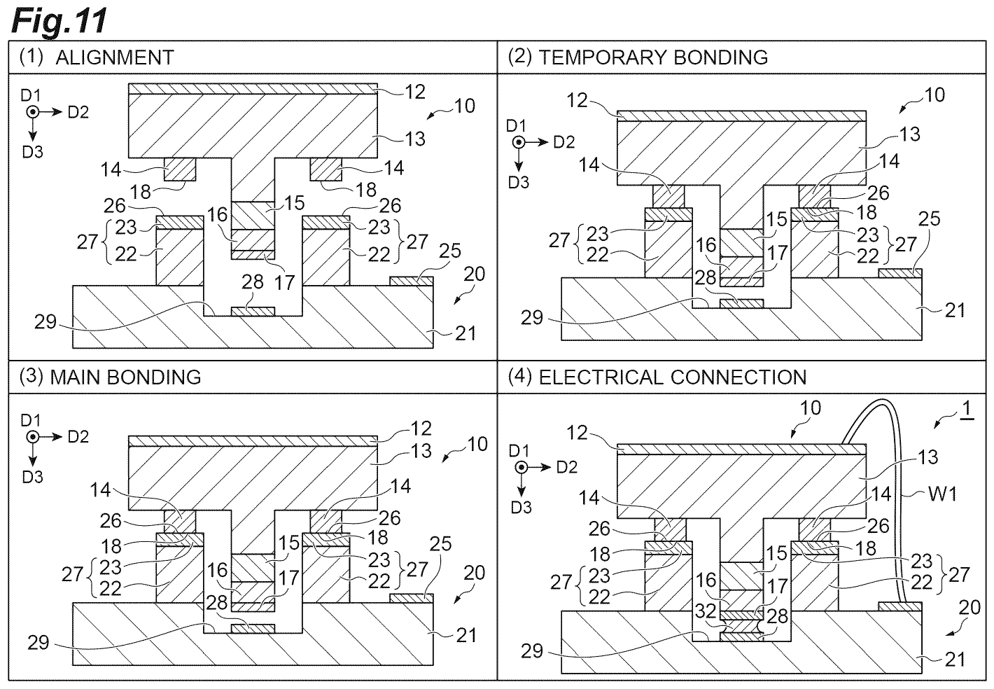

FIG. 11 is a drawing schematically showing steps subsequent to the hydrophilic treatment in the method for manufacturing the optical semiconductor device 1. As shown in (1) of FIG. 11, the first semiconductor element 10 is aligned with the second semiconductor element 20. At this time, with the first semiconductor element 10 spaced apart from the second semiconductor element 20, the position of the first bonding surface 18 in the first direction D1 and the second direction D2 is aligned with the position of the second bonding surface 26 in the first direction D1 and the second direction D2.

More specifically, the end surface 11 and the optical waveguide 24 are aligned so as to be optically coupled to each other by making the first bonding surface 18 of the first semiconductor element 10 face the second bonding surface 26 of the second semiconductor element 20 with a space therebetween (alignment step). This alignment is performed with the first bonding surface 18 spaced apart from the second bonding surface 26 at a short distance. For example, the distance between the first bonding surface 18 and the second bonding surface 26 when performing this alignment is 1 μm or more and less than 100 μm (for example, several μm).

As shown in FIGS. 10 and 11, after the above-described alignment is performed, the first semiconductor element 10 is moved in the third direction D3 to bring the first bonding surface 18 into contact with the second bonding surface 26, thereby performing temporary bonding of the first semiconductor element 10 to the second semiconductor element 20. At this time, the first bonding surface 18 is brought into contact with the second bonding surface 26 at the first temperature, and at least one of the first semiconductor element 10 and the second semiconductor element 20 is pressed to temporarily bond these to each other (temporary bonding step). For example, the temporary bonding time is several tens of seconds (for example, 10 seconds or less).

The first temperature is, for example, 20° C. or higher and 40° C. or lower. The first temperature may be normal temperature (or room temperature). For example, in the case of temporary bonding, it is not necessary to heat the first bonding surface 18 and the second bonding surface 26. When the temporary bonding is performed, the hydrogen atom of the OH group of the first bonding surface 18 bonds to the hydrogen atom of the OH group of the second bonding surface 26, forming a bonded portion 30 that is a portion where the first bonding surface 18 and the second bonding surface 26 are bonded to each other. The strength of the bonded portion 30 is, for example, 5 MPa or more. The bonded portion 30 is an example of a first bonded portion.

After the temporary bonding, the first semiconductor element 10 and the second semiconductor element 20 are heated for main bonding between the first bonding surface 18 and the second bonding surface 26 at a second temperature higher than the first temperature (main bonding step). The second temperature is, for example, 100° C. or higher and 300° C. or lower. As an example, the second temperature may be 150° C. At this time, the bonded portion 30 is heated to cause a hydrolysis reaction in the bonded portion 30. As a result, the OH groups in the bonded portion 30 are decomposed and the hydrogen atoms are released from the bonded portion 30, and the first bonding surface 18 and the second bonding surface 26 are bonded to each other through the oxygen atoms. At this time, the first bonding surface 18 and the second bonding surface 26 are bonded to each other in a hydrophilic manner, and an oxide film 31 formed of the oxygen atoms is formed at the bonded portion 30. In the hydrophilically bonded state, a bond bridge of —O— is formed at the bonded portion 30, resulting in a state in which the first bonding surface 18 is firmly bonded to the second bonding surface 26. In order to obtain a strong bond through hydrophilic bonding, the first bonding surface 18 and the second bonding surface 26 each may have good flatness.

After the main bonding, the first semiconductor element 10 is electrically connected to the second semiconductor element 20 (electrical connection step). Specifically, an electrical bonding agent 32 is applied between the electrode 28 of the second semiconductor element 20 and the electrode 17 of the first semiconductor element 10 to electrically connect the electrode 17 to the electrode 28. The electrical bonding agent 32 is, for example, a conductive paste. As an example, the electrical bonding agent 32 is a silver paste. More specifically, after the electrical bonding agent 32 is applied, the first semiconductor element 10 and the second semiconductor element 20 are heated at a third temperature higher than the first temperature to bond the electrodes 17 and 28 to each other. The third temperature is set to a temperature at which the electrical bonding agent 32 is melted. For example, the third temperature is set higher than the melting point of a single metal or alloy contained in the electrical bonding agent 32. If the electrical bonding agent 32 is solder, the third temperature is set to at least the melting point of the solder. The third temperature is, for example, 120° C. or more and 350° C. or less. As an example, the third temperature may be 190° C. After the electrodes 17 and 28 are bonded to each other, the electrode 12 of the first semiconductor element 10 is electrically connected to the electrode 25 of the second semiconductor element 20 through a bonding wire W1. After the first semiconductor element 10 is electrically connected to the second semiconductor element 20 as described above, a series of steps of the method for manufacturing the optical semiconductor device 1 according to the present embodiment is completed.

Next, the effects obtained from the optical semiconductor device 1 according to the present embodiment and the method for manufacturing the optical semiconductor device 1 will be described. In the optical semiconductor device 1 and the method for manufacturing the optical semiconductor device 1, the first semiconductor element 10 has the first bonding surface 18 and the end surface 11, and the second semiconductor element 20 has the second bonding surface 26 and the optical waveguide 24. The end surface 11 of the first semiconductor element 10 and the optical waveguide 24 of the second semiconductor element 20 are optically coupled to each other, and the first bonding surface 18 and the second bonding surface 26 are bonded to each other in a hydrophilic manner. Hydrophilic bonding does not require heating after the alignment of the first bonding surface 18 with respect to the second bonding surface 26. In the present embodiment, the first bonding surface 18 of the first semiconductor element 10 is fixed to the second bonding surface 26 of the second semiconductor element 20 during temporary bonding. Therefore, it is possible to suppress the misalignment of the first semiconductor element 10 with respect to the second semiconductor element 20 due to heating. As a result, the mounting of the first semiconductor element 10 with respect to the second semiconductor element 20 can be performed with high accuracy by suppressing misalignment. In this manner, it is possible to suppress a decrease in the efficiency of optical coupling due to the alignment between the end surface 11 of the first semiconductor element 10 and the optical waveguide 24 of the second semiconductor element 20 after bonding.

As described above, the oxide film 31 may be formed at the bonded portion 30, which is a portion where the first bonding surface 18 and the second bonding surface 26 are bonded to each other in a hydrophilic manner. In this case, the first bonding surface 18 can be firmly bonded to the second bonding surface 26 by the oxygen atoms forming the oxide film 31.

As described above, in the hydrophilizing step, the first bonding surface 18 may be made hydrophilic by irradiating the first bonding surface 18 with ultraviolet light in an air exposure environment. In this case, damage to the first bonding surface 18 can be suppressed when the first bonding surface 18 is made hydrophilic. This reduces the deterioration of hydrophilic bonding caused by the roughening of the first bonding surface 18. For example, the thickness of the oxide film 31 is 10 nm or less.

As described above, in the hydrophilizing step, the first bonding surface 18 may be made hydrophilic by exposing the first bonding surface 18 to oxygen plasma in a vacuum environment. In this case, when the first bonding surface 18 is made hydrophilic, and the thick oxide film 31 can be formed on the first bonding surface 18. The bonding strength can be enhanced by a thick oxide film. For example, the thickness of the oxide film 31 is 10 nm or more.

As described above, in the hydrophilizing step, the first bonding surface 18 may be made hydrophilic by exposing the first bonding surface 18 to nitrogen plasma in a vacuum environment.

As described above, the strength of the bonded portion 30, which is a portion where the first bonding surface 18 and the second bonding surface 26 are bonded to each other after the temporary bonding step, may be 5 MPa or more. In this case, the first semiconductor element 10 can be firmly bonded to the second semiconductor element 20 in the temporary bonding.

As described above, the distance between the first bonding surface 18 and the second bonding surface 26 during the alignment step may be 1 μm or more and less than 100 μm. In this case, since the distance between the first bonding surface 18 and the second bonding surface 26 during alignment can be reduced, misalignment of the first bonding surface 18 with respect to the second bonding surface 26 can be more reliably suppressed.

As described above, the first temperature may be 20° C. or more and 40° C. or less, and the second temperature may be 100° C. or more and 300° C. or less. In this case, since the first temperature during the temporary bonding can be room temperature, misalignment due to heating can be more reliably suppressed.

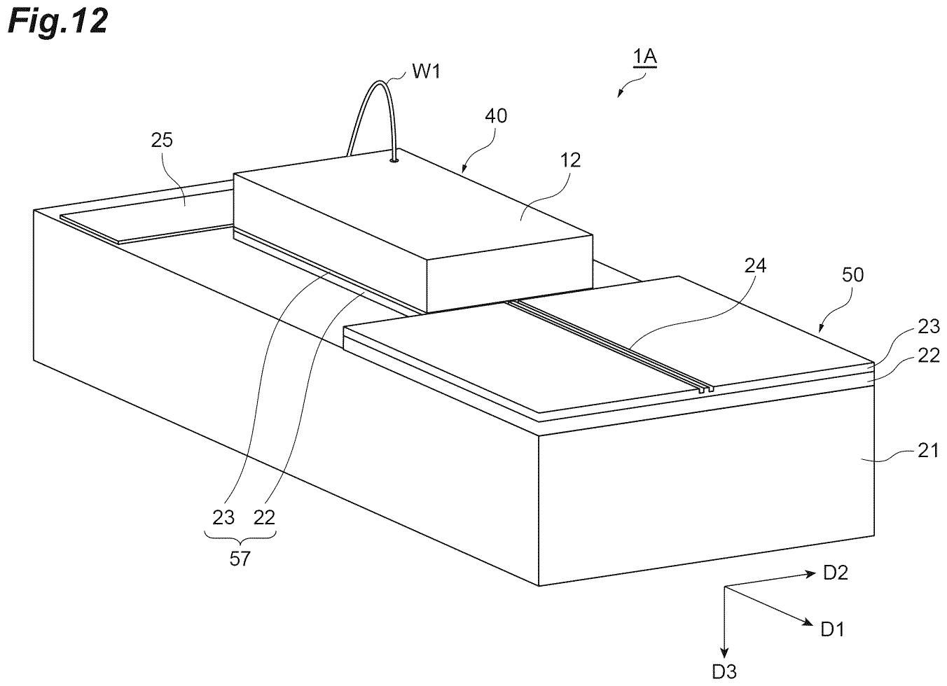

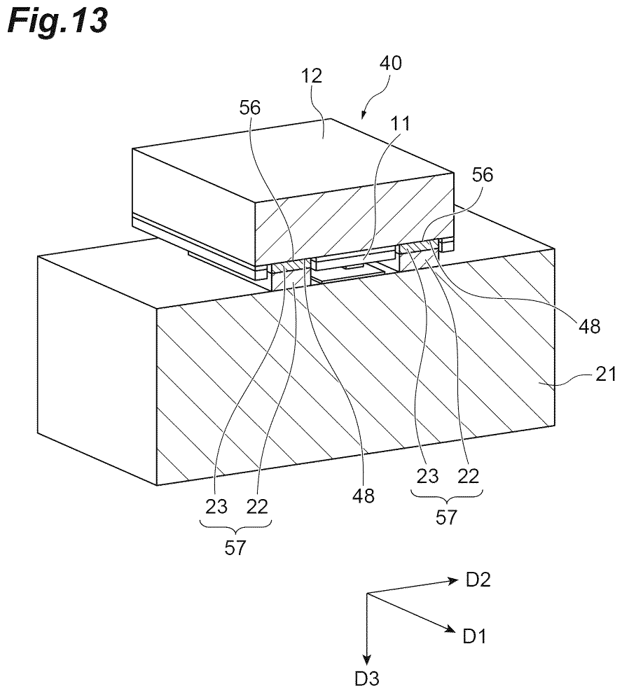

Next, an optical semiconductor device 1A according to a second embodiment will be described with reference to FIGS. 12 to 14. The optical semiconductor device 1A includes a first semiconductor element 40 and a second semiconductor element 50. The first semiconductor element 40 has an end surface 11, similarly to the first semiconductor element 10 described above. The second semiconductor element 50 has a second bonding surface 56 and a support portion 57 that are shorter in length in the second direction D2 than the second bonding surface 26 and the support portion 27.

The first semiconductor element 40 has an electrode 12, an n-InP layer 13, a p-InP layer 44, an MQW layer 15, a p-InP layer 46, an electrode 17, and an n-InPlayer 47. The p-InP layer 44 has a recessed portion 44b that is recessed in a direction opposite to the third direction D3. The recessed portion 44b is defined by a first side portion 44c in contact with the MQW layer 15, a bottom portion 44d extending from the first side portion 44c in a direction opposite to the MQW layer 15, and a second side portion 44f protruding in the third direction D3 at the end of the bottom portion 44d opposite to the first side portion 44c. The n-InP layer 47 is formed at the end of each of the first side portion 44c and the second side portion 44f in the third direction D3. The p-InP layer 46 is formed at the end of the n-InP layer 47 in the third direction D3. The n-InP layer 47 is provided to suppress the flow of a current from the p-InP layer 46 to the p-InP layer 44.

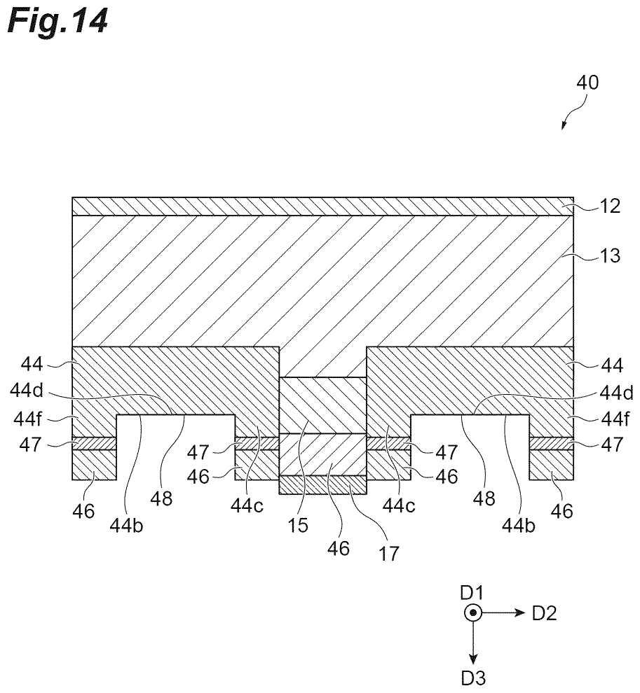

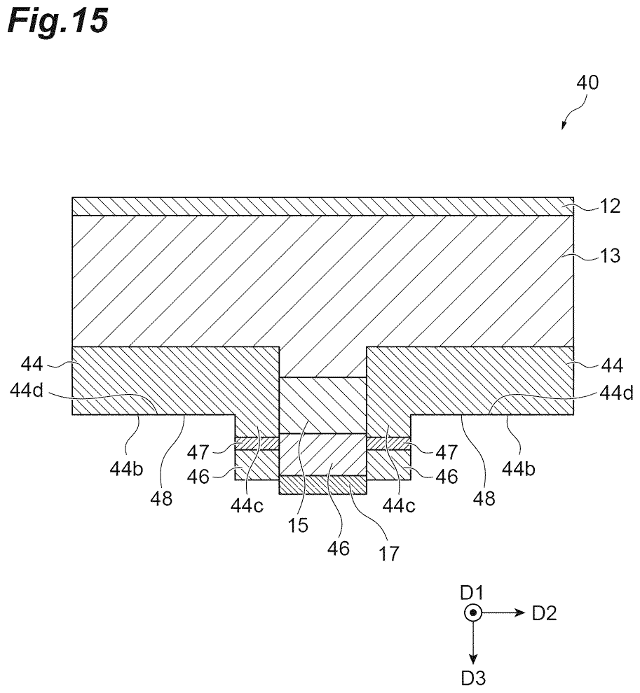

As shown in a modification example of FIG. 15, the first semiconductor element 40 may not include the second side portion 44f shown in FIG. 14, the n-InP layer 47 formed on the second side portion 44f, and the p-InP layer 46 formed on the n-InP layer 47. In this manner, the shape of the first semiconductor element 40 can be changed as appropriate. The first semiconductor element 40 has a first bonding surface 48 at the end of the bottom portion 44d in the third direction D3. The first bonding surface 48 is formed by etching. In this case, the position of the first bonding surface 48 in the third direction D3 can be adjusted by the amount of etching.

For example, the position of the first bonding surface 48 in the third direction D3 may be set to the position of the optical axis of the optical signal output from the MQW layer 15 in the third direction D3. The length of the first bonding surface 48 in the second direction D2 is larger than the length of the support portion 57 in the second direction D2. The first semiconductor element 40 moves in the second direction D2 when aligned. For example, when the length of the first bonding surface 48 in the second direction D2 is equal to or greater than the amount of the alignment allowance, the bonding area of the second bonding surface 56 with respect to the first bonding surface 48 is more reliably ensured.

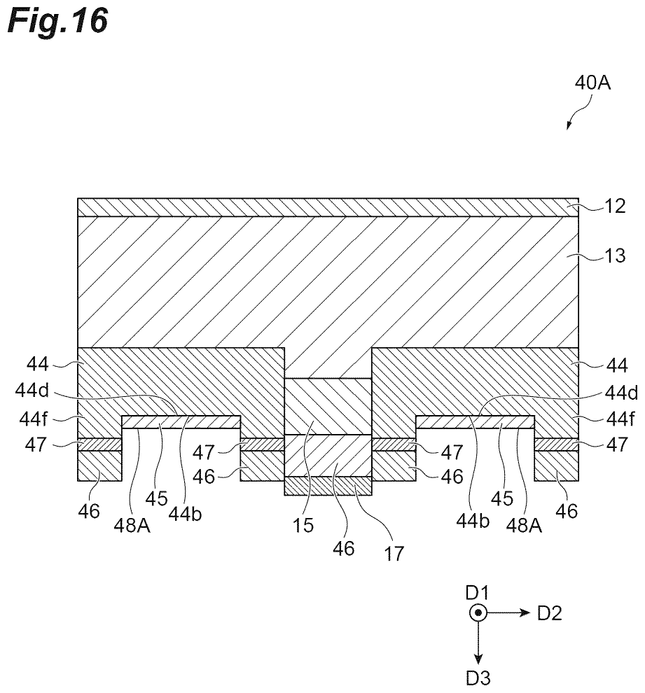

FIG. 16 is a drawing schematically showing a cross section of a first semiconductor element 40A according to another modification example. The first semiconductor element 40A is different from the first semiconductor element 40 described above in that a bonding layer 45 is formed on the bottom portion 44d of the recessed portion 44b. For example, the material of the bonding layer 45 is the same as the material of the MQW layer 15. The first semiconductor element 40A has a first bonding surface 48A, and the first bonding surface 48A is formed on the bonding layer 45. The first bonding surface 48A extends in both the first direction D1 and the second direction D2 at the end of the bonding layer 45 in the third direction D3. The first bonding surface 48A is formed by, for example, etching. The first bonding surface 48A may be formed by dry etching, wet etching, or epitaxial growth together with the MQW layer 15. In this case, since the flatness of the first bonding surface 48A can be improved, the first bonding surface 48A can be a surface suitable for hydrophilic bonding.

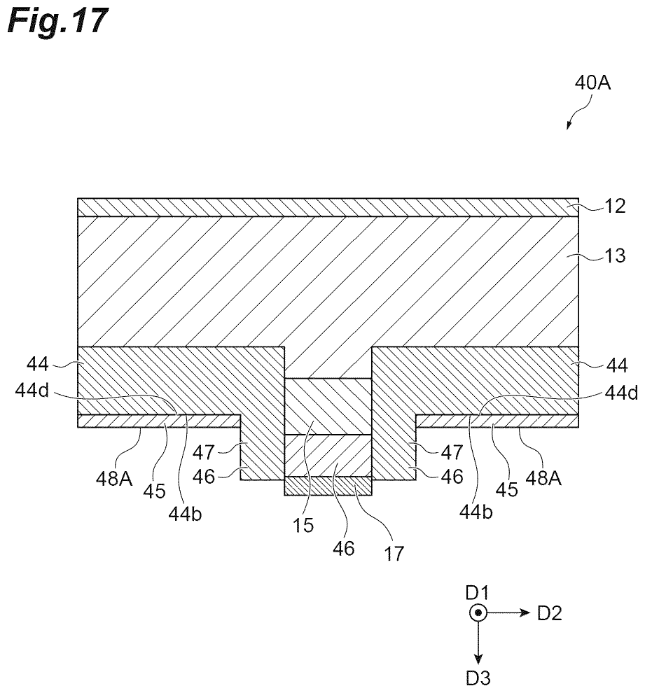

As shown in a modification example of FIG. 17, the first semiconductor element 40A may not include the second side portion 44f shown in FIG. 16, the n-InP layer 47 formed on the second side portion 44f, and the p-InP layer 46 formed on the n-InP layer 47. In the first semiconductor element 40A shown in FIG. 17, the end of the first bonding surface 48A opposite to the mesa is aligned along the third direction D3 with the end of the p-InP layer 44 opposite to the mesa. That is, the end of the first bonding surface 48A opposite to the mesa reaches the end of the p-InP layer 44 opposite to the mesa. Therefore, in the first semiconductor element 40A according to the modification example of FIG. 17, the area of the first bonding surface 48A can be made larger than that of the first semiconductor element 40A in FIG. 16.

Next, a method for manufacturing the optical semiconductor device 1A will be described. Since some of the steps of the method for manufacturing the optical semiconductor device 1A are the same as some of the steps of the method for manufacturing the optical semiconductor device 1 described above, repeated description thereof will be omitted as appropriate. A method for manufacturing the optical semiconductor device 1A having the first semiconductor element 40 will be described below. Since the method for manufacturing the optical semiconductor device 1A having the first semiconductor element 40A is similar to the method for manufacturing the optical semiconductor device 1A having the first semiconductor element 40, description thereof will be omitted.

First, the first semiconductor element 40 and the second semiconductor element 50 are prepared, and the first bonding surface 48 of the first semiconductor element 40 is subjected to a hydrophilic treatment (a step of making the first bonding surface hydrophilic). The hydrophilic treatment is performed by irradiating the first bonding surface 48 with ultraviolet light in an air exposure environment or by exposing the first bonding surface 48 to oxygen plasma or nitrogen plasma in a vacuum environment, as in the first embodiment. At this time, the second bonding surface 56 of the second semiconductor element 50 may be made hydrophilic. At this time, OH groups are formed on each of the first bonding surface 48 and the second bonding surface 56.

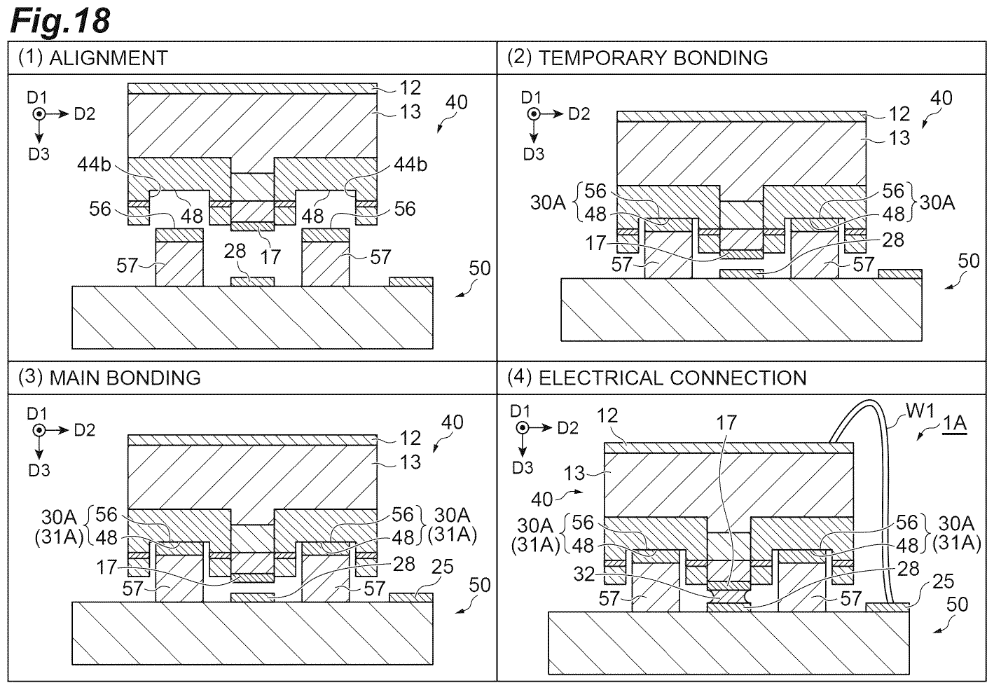

FIG. 18 is a drawing schematically showing the steps of the method for manufacturing the optical semiconductor device 1A. As shown in (1) of FIG. 18, the first semiconductor element 40 is aligned with the second semiconductor element 50. At this time, with the first semiconductor element 40 spaced apart from the second semiconductor element 50, the position of the recessed portion 44b in the first direction D1 and the second direction D2 is aligned with the position of the second bonding surface 56 in the first direction D1 and the second direction D2. Then, the end surface 11 and the optical waveguide 24 are aligned so as to be optically coupled to each other (alignment step).

After the alignment, temporary bonding and main bonding are performed in the same manner as in the first embodiment. Specifically, the first semiconductor element 40 is moved in the third direction D3 to bring the first bonding surface 48 into contact with the second bonding surface 56, and at least one of the first semiconductor element 40 and the second semiconductor element 50 is pressed to temporarily bond these to each other (temporary bonding step). At this time, the hydrogen atom of the OH group of the first bonding surface 48 bonds to the hydrogen atom of the OH group of the second bonding surface 56, forming a bonded portion 30A that is a portion where the first bonding surface 48 and the second bonding surface 56 are bonded to each other.

After the temporary bonding, the first semiconductor element 40 and the second semiconductor element 50 are heated in an environment of the second temperature for main bonding (main bonding step). At this time, the OH groups in the bonded portion 30A are decomposed and the hydrogen atoms are released from the bonded portion 30A, and the first bonding surface 48 and the second bonding surface 56 are bonded to each other through the oxygen atoms. The first bonding surface 48 and the second bonding surface 56 are bonded to each other in a hydrophilic manner, and an oxide film 31A formed of oxygen atoms is formed at the bonded portion 30A.

After the main bonding, the first semiconductor element 40 is electrically connected to the second semiconductor element 50 (electrical connection step). Specifically, the electrical bonding agent 32 is applied between the electrode 28 of the second semiconductor element 50 and the electrode 17 of the first semiconductor element 40 to electrically connect the electrode 17 to the electrode 28. The electrical bonding agent 32 is, for example, a conductive paste. As an example, the electrical bonding agent 32 is a silver paste. More specifically, after the electrical bonding agent 32 is applied, the first semiconductor element 40 and the second semiconductor element 50 are heated at a third temperature higher than the first temperature to bond the electrodes 17 and 28 to each other. The third temperature is, for example, 120° C. or more and 350° C. or less. As an example, the third temperature may be 190° C. After the electrodes 17 and 28 are bonded to each other, the electrode 12 of the first semiconductor element 40 is connected to the electrode 25 of the second semiconductor element 50 through a bonding wire W1. After the first semiconductor element 40 is electrically connected to the second semiconductor element 50 as described above, a series of steps of the method for manufacturing the optical semiconductor device 1A are completed.

As described above, in the optical semiconductor device 1A according to the second embodiment and the method for manufacturing the optical semiconductor device 1A, the first bonding surface 48 is subjected to a hydrophilic treatment, and the first semiconductor element 40 is temporarily bonded to the second semiconductor element 50 in an environment of the first temperature. In the temporary bonding, the first bonding surface 48 is fixed to the second bonding surface 56. Therefore, since it is possible to suppress the misalignment of the first semiconductor element 40 with respect to the second semiconductor element 50 due to heating, it is possible to obtain the same effects as those of the optical semiconductor device 1 described above. In addition, in the second embodiment, the first semiconductor element 40 has the recessed portion 44b, and the first bonding surface 48 is formed on the bottom portion 44d of the recessed portion 44b. Therefore, the alignment of the first bonding surface 48 with respect to the second bonding surface 56 becomes easier.

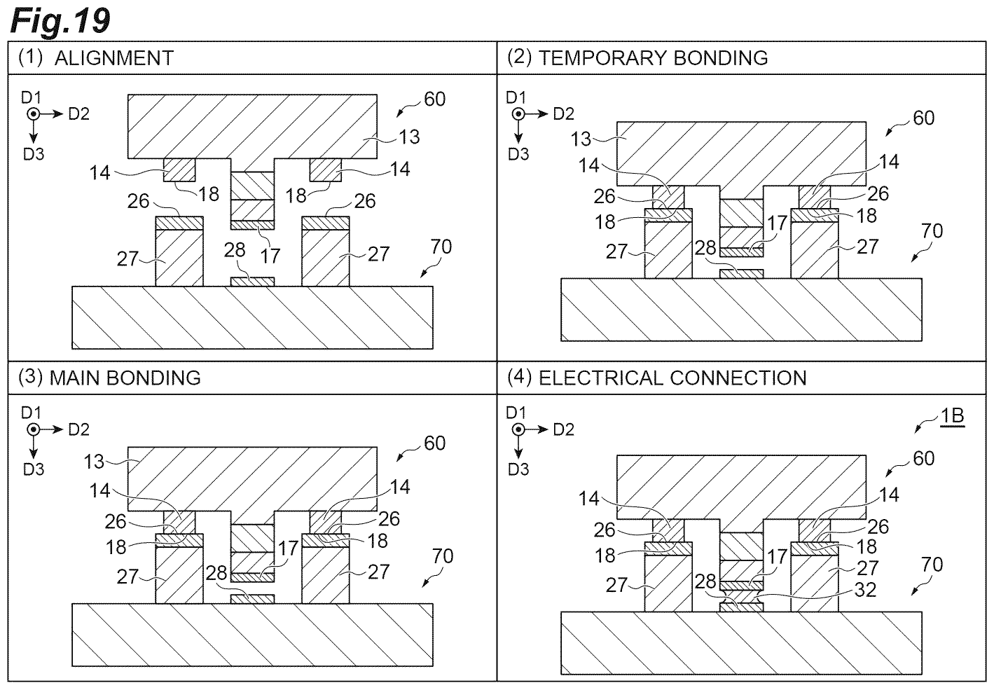

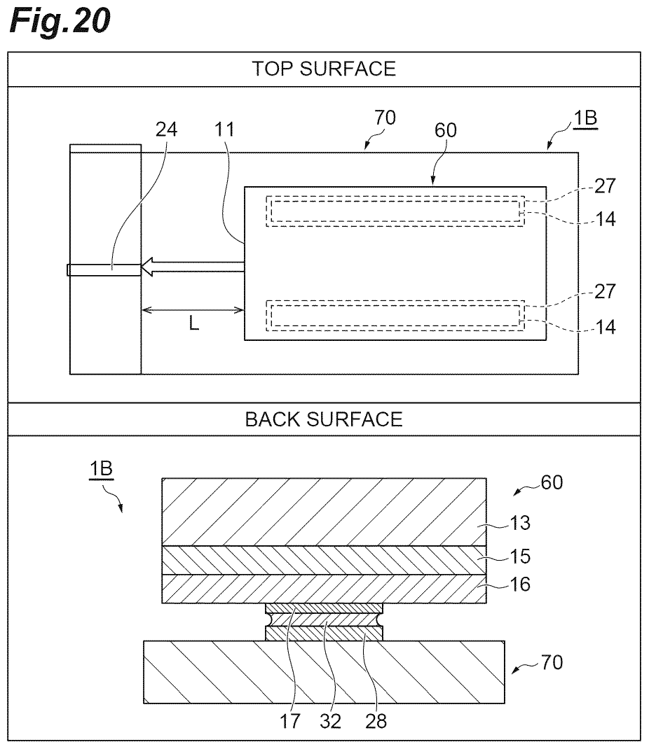

Next, an optical semiconductor device 1B and a method for manufacturing the optical semiconductor device 1B according to a third embodiment will be described with reference to FIGS. 19 and 20. The drawing of the back surface of FIG. 20 is an enlarged view of a portion between a pair of support portions 27 on the top surface of FIG. 20. The optical semiconductor device 1B includes a first semiconductor element 60 and a second semiconductor element 70. The first semiconductor element 60 is different from the first semiconductor element 10 in that the first semiconductor element 60 does not have the electrode 12 described above but has two electrodes 17. One of the two electrodes 17 has an extending portion 17b that passes upward through the p-InP layer 16 and the MQW layer 15 and reaches the n-InP layer 13. The second semiconductor element 70 is different from the second semiconductor element 20 in that the second semiconductor element 70 does not have the electrode 25 described above but has two electrodes 28. In the optical semiconductor device 1B, the bonding wire W1 is not required. For example, the distance L from the end surface 11 to the optical waveguide 24 is 50 μm or less.

A method for manufacturing the optical semiconductor device 1B will be described. A step of making the first bonding surface 18 hydrophilic, an alignment step, a temporary bonding step, and a main bonding step are the same as those in the first embodiment. In the third embodiment, an electrical bonding agent 32 is applied between each of the two electrodes 28 of the second semiconductor element 70 and each of the two electrodes 17 of the first semiconductor element 60 to make an electrical connection therebetween. After the first semiconductor element 60 is electrically connected to the second semiconductor element 70 as described above, a series of steps of the method for manufacturing the optical semiconductor device 1B are completed. From the optical semiconductor device 1B and the method for manufacturing the optical semiconductor device 1B according to the third embodiment, the same effects as in the first embodiment and the effect of making wire bonding unnecessary are obtained.

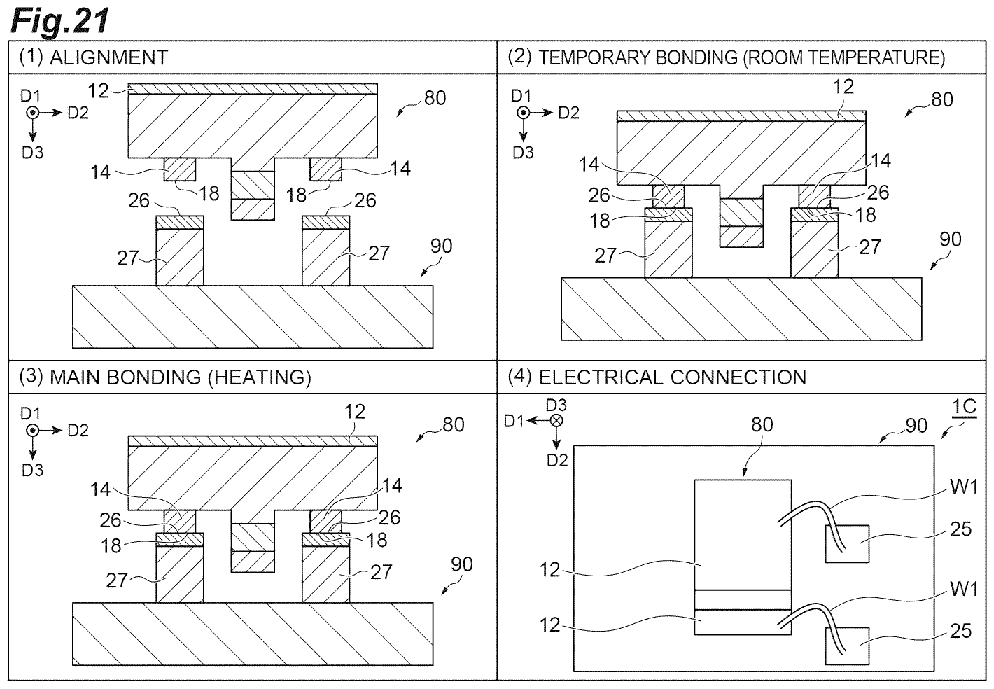

An optical semiconductor device IC and a method for manufacturing the optical semiconductor device 1C according to a fourth embodiment will be described with reference to FIG. 21. The optical semiconductor device IC includes a first semiconductor element 80 and a second semiconductor element 90. As shown in (4) of FIG. 21, the first semiconductor element 80 is different from the first semiconductor element 10 in that the first semiconductor element 80 has two electrodes 12, and the second semiconductor element 90 is different from the second semiconductor element 20 in that the second semiconductor element 90 has two electrodes 25. The two electrodes 12 are spaced apart from each other. The two electrodes 12 are, for example, an n-electrode and a p-electrode. For example, the two electrodes 12 are aligned along the second direction D2, and the two electrodes 25 are aligned along the second direction D2.

In the method for manufacturing the optical semiconductor device 1C, a step of making the first bonding surface 18 hydrophilic, an alignment step, a temporary bonding step, and a main bonding step are the same as those in the first embodiment. In the fourth embodiment, each of the two electrodes 25 of the second semiconductor element 90 is connected to each of the two electrodes 12 of the first semiconductor element 80 through the bonding wire W1. After the first semiconductor element 80 is electrically connected to the second semiconductor element 90 as described above, a series of steps of the method for manufacturing the optical semiconductor device IC are completed.

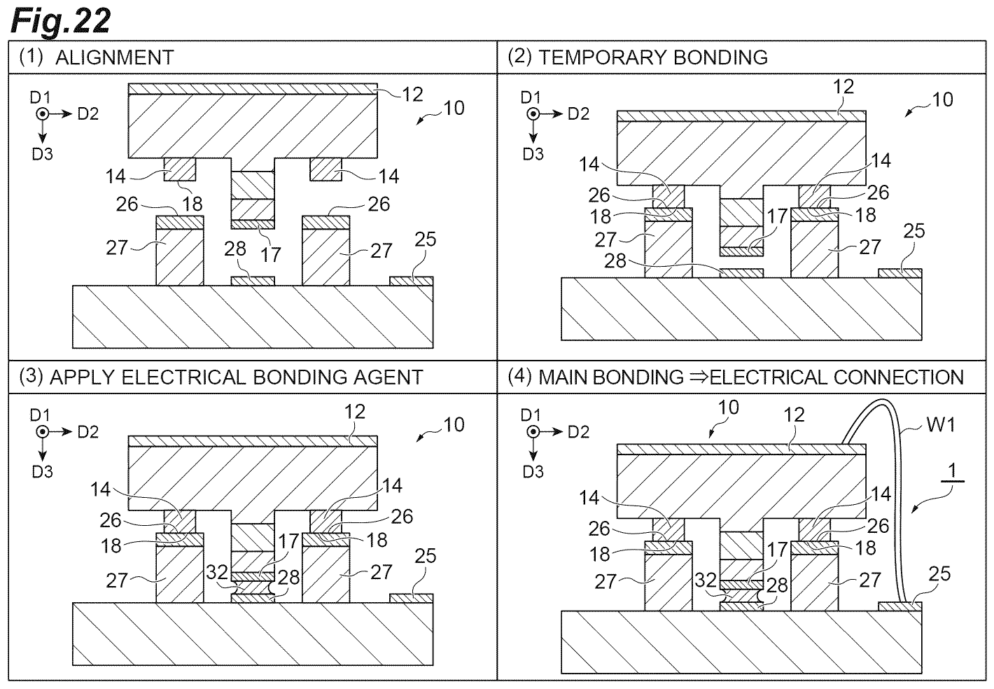

Next, a method for manufacturing the optical semiconductor device 1 according to a fifth embodiment will be described with reference to FIG. 22. As shown in FIG. 22, in the method for manufacturing the optical semiconductor device 1 according to the fifth embodiment, a step of making the first bonding surface 18 hydrophilic, an alignment step, and a temporary bonding step are the same as those in the first embodiment. In the fifth embodiment, after the temporary fixing and before the final fixing, the electrical bonding agent 32 is applied (a step of applying an electrical bonding agent). At this time, the electrical bonding agent 32 is applied between the electrode 28 and the electrode 17.

After the electrical bonding agent 32 is applied, main bonding is performed. The method of main bonding is the same as in the first embodiment. At this time, the electrical bonding agent 32 is baked at the same time as baking for the main bonding. Then, the electrode 25 of the second semiconductor element 20 is connected to the electrode 12 of the first semiconductor element 10 through the bonding wire W1. After the first semiconductor element 10 is electrically connected to the second semiconductor element 20 as described above, a series of steps of the method for manufacturing the optical semiconductor device 1 are completed. From the method for manufacturing the optical semiconductor device 1 according to the fifth embodiment, the same effects as in the first embodiment and the effect of enabling the simplification of the steps because the electrical bonding agent 32 can be baked at the same time as baking for the main bonding are obtained.

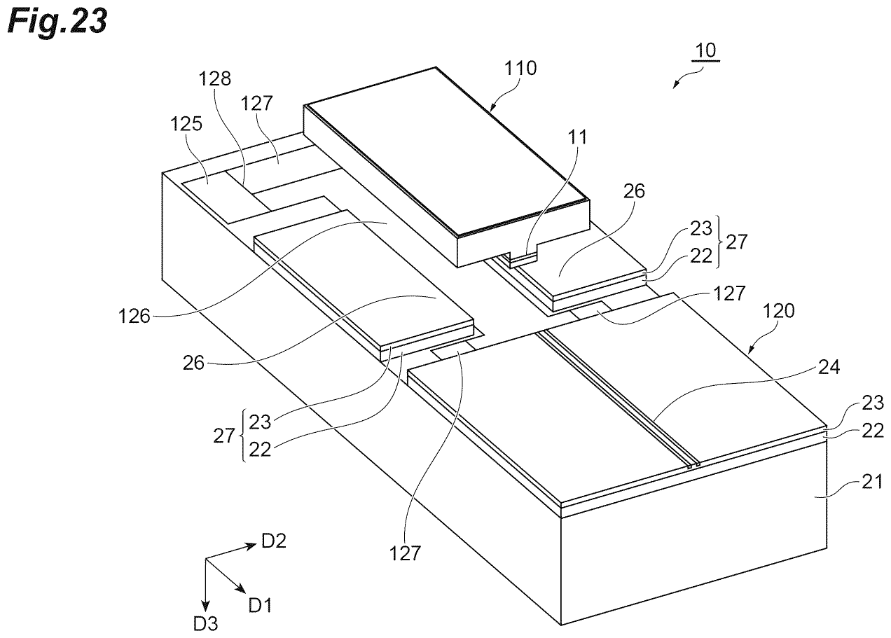

An optical semiconductor device ID according to a sixth embodiment will be described with reference to FIG. 23. The optical semiconductor device ID includes a first semiconductor element 110 and a second semiconductor element 120. The second semiconductor element 120, similarly to the above-described second semiconductor element 20, includes a first layer 21, a second layer 22 located on the first layer 21, and a third layer 23 located on the second layer 22. The second layer 22 extends along a first direction D1, which is the direction in which the optical waveguide 24 extends, and along a second direction D2, which crosses the first direction D1. The two third layers 23 and the two second layers 22 aligned along the second direction D2 are a support portion 27 that supports the first semiconductor element 110. The second semiconductor element 120 has a second bonding surface 26, which is the upper surface of the support portion 27. The second semiconductor element 120 has two second bonding surfaces 26, and the two second bonding surfaces 26 are aligned along the second direction D2.

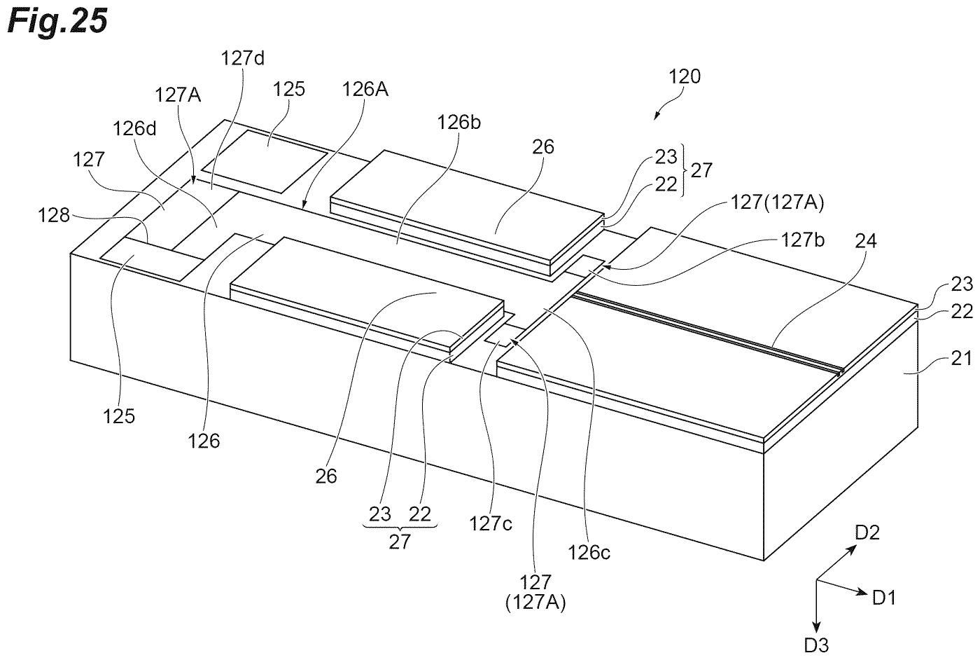

The second semiconductor element 120 has an electrode 125. The electrode 125 is provided, for example, on the first layer 21. The electrode 125 is formed of, for example, either gold (Au), titanium (Ti), or platinum (Pt). The electrode 125 is located, for example, at an end of the first layer 21 on the opposite side in the first direction D1 and the opposite side in the second direction D2 relative to the second semiconductor element 120 in plan view (when the second semiconductor element 120 is viewed from above). The second semiconductor element 120 may have multiple electrodes 125 (see FIG. 25). In this case, the two electrodes 125 may be aligned along the second direction D2 on the opposite side of the first layer 21 in the first direction D1 relative to the second semiconductor element 120 in plan view.

The second semiconductor element 120 has a first bonding agent layer 126 formed of an electrical bonding agent and a second bonding agent layer 127 formed on the first bonding agent layer 126 and formed of an electrical bonding agent, before the first semiconductor element 110 is bonded to the second semiconductor element 120. For example, each of the first bonding agent layer 126 and the second bonding agent layer 127 is solder. As an example, the material of the first bonding agent layer 126 and the material of the second bonding agent layer 127 are gold-tin (AuSn). However, the material of the first bonding agent layer 126 and the material of the second bonding agent layer 127 may also be tin-silver-copper (SnAgCu) and are not particularly limited. The first bonding agent layer 126 and the second bonding agent layer 127 melt when heated. The second bonding agent layer 127 melted on the first bonding agent layer 126 flows into the portion of the first bonding agent layer 126 where the second bonding agent layer 127 is not formed (on the portion of the first bonding agent layer 126 exposed before heating, on a first bonding agent layer region 126A described later).

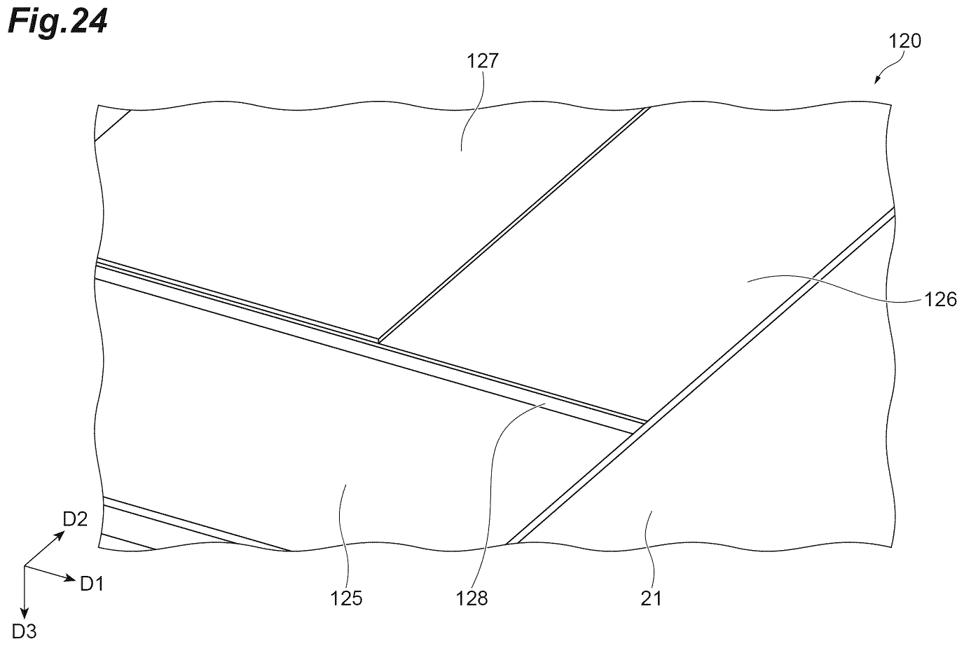

FIG. 24 is an enlarged perspective view of a portion of the first bonding agent layer 126 and a portion of the second bonding agent layer 127. As shown in FIGS. 23 and 24, the second semiconductor element 120 has a flow stopper 128 located between the first and second bonding agent layers 126, 127 and the electrode 125. The flow stopper 128 prevents the molten solder (the first bonding agent layer 126 and the second bonding agent layer 127) from flowing into the electrode 125. The flow stopper 128 is formed of, for example, Pt. For example, the first bonding agent layer 126 and the second bonding agent layer 127 are aligned along the first direction D1 at a position facing the electrode 125. The flow stopper 128 extends along the first direction D1 between the portion where the first bonding agent layer 126 and the second bonding agent layer 127 are aligned, and the electrode 125.

FIG. 25 is a perspective view showing the second semiconductor element 120. As shown in FIG. 25, before the first semiconductor element 110 is bonded to the second semiconductor element 120, the second semiconductor element 120 has the first bonding agent layer region 126A where only the first bonding agent layer 126 is formed, and a second bonding agent layer region 127A where the second bonding agent layer 127 is formed on the first bonding agent layer 126. For example, the second semiconductor element 120 has one first bonding agent layer region 126A and multiple second bonding agent layer regions 127A. The first bonding agent layer region 126A includes, for example, a first portion 126b located between the two support portions 27 aligned along the second direction D2, a second portion 126c located at the end of the first portion 126b in the first direction D1, and a third portion 126d located at the end of the first portion 126b in the direction opposite to the first direction D1.

The first portion 126b has a rectangular shape extending along the first direction D1. The length of the first portion 126b in the first direction D1 is greater than the length of the support portion 27 in the first direction D1. The end of the first portion 126b in the first direction D1 protrudes in the first direction D1 from the end of the support portion 27 in the first direction D1. The end of the first portion 126b in the direction opposite to the first direction D1 protrudes in the opposite direction from the end of the support portion 27 in the opposite direction. The second portion 126c has a rectangular shape extending along the second direction D2. The end of the second portion 126c in the second direction D2 protrudes in the second direction D2 from the end of the first portion 126b in the second direction D2. The end of the second portion 126c in the direction opposite to the second direction D2 protrudes in the opposite direction from the end of the first portion 126b in the opposite direction.

In the plan view of the second semiconductor element 120, the first portion 126b and the second portion 126c form a T-shape. The third portion 126d has a rectangular shape extending along the second direction D2. The third portion 126d protrudes in the direction opposite to the second direction D2 from the first portion 126b. In the plan view of the second semiconductor element 120, for example, the first portion 126b and the third portion 126d form an L-shape. The flow stopper 128 is formed in the direction opposite to the second direction D2 of the third portion 126d.

The second bonding agent layer region 127A includes, for example, a first portion 127b and a second portion 127c located in the first direction D1 relative to the support portion 27, and a third portion 127d located in the direction opposite to the first direction D1 relative to the first bonding agent layer region 126A. The first portion 127b is located in the first direction D1 relative to the support portion 27 located in the second direction D2 among the two support portions 27. The first portion 127b is located in the second direction D2 relative to the second portion 126c. The first portion 127b is, for example, rectangular in shape.

The second portion 127c is located in the first direction D1 relative to the support portion 27 that is located in the direction opposite to the second direction D2 among the two support portions 27. The second portion 127c and the first portion 127b are aligned along the second direction D2. The second portion 127c and the first portion 127b sandwich the second portion 126c along the second direction D2. The second portion 127c is, for example, rectangular in shape. The third portion 127d has a rectangular shape extending along the second direction D2. The third portion 127d is located in the direction opposite to the first direction D1 relative to the third portion 126d of the first bonding agent layer region 126A. The flow stopper 128 is formed in the direction opposite to the second direction D2 of the third portion 127d.

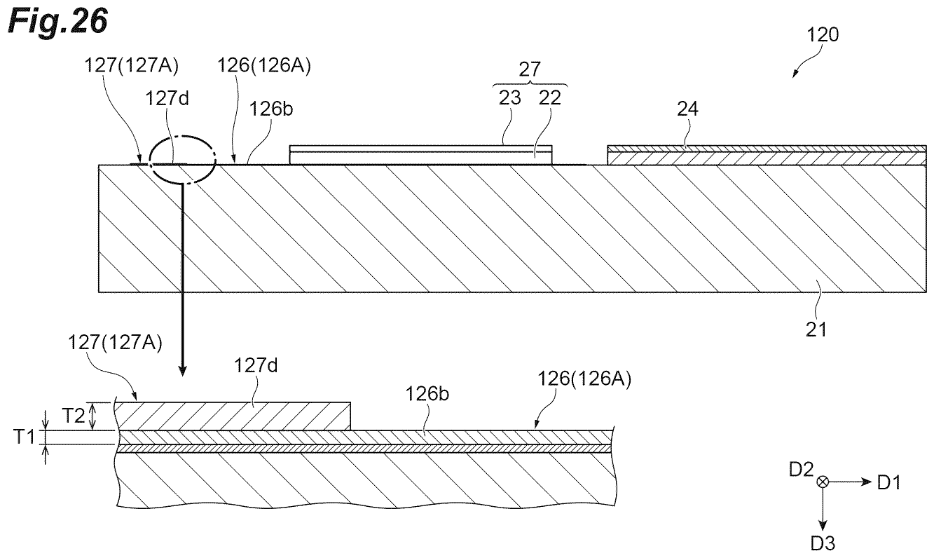

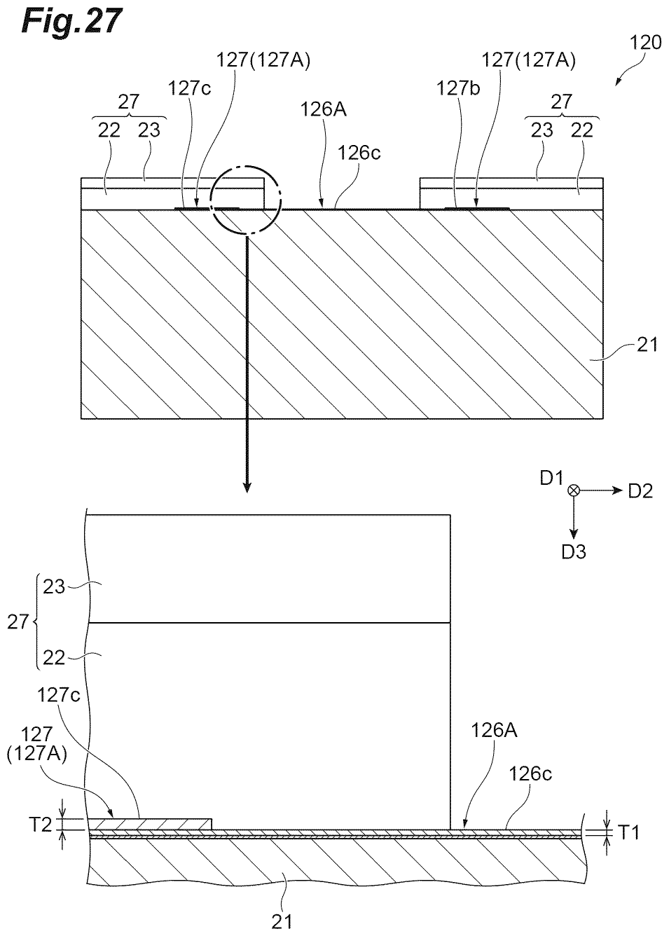

FIG. 26 is a cross-sectional view and a partially enlarged view of the first bonding agent layer 126 (first portion 126b) and the second bonding agent layer 127 (third portion 127d) when cut along a plane extending in the first direction D1 and the third direction D3. FIG. 27 is a cross-sectional view and a partially enlarged view of the first bonding agent layer 126 (second portion 126c) and the second bonding agent layer 127 (first portion 127b and second portion 127c) when cut along a plane extending in the second direction D2 and the third direction D3. As shown in FIGS. 26 and 27, for example, a thickness T2 of the second bonding agent layer 127 is greater than a thickness T1 of the first bonding agent layer 126.

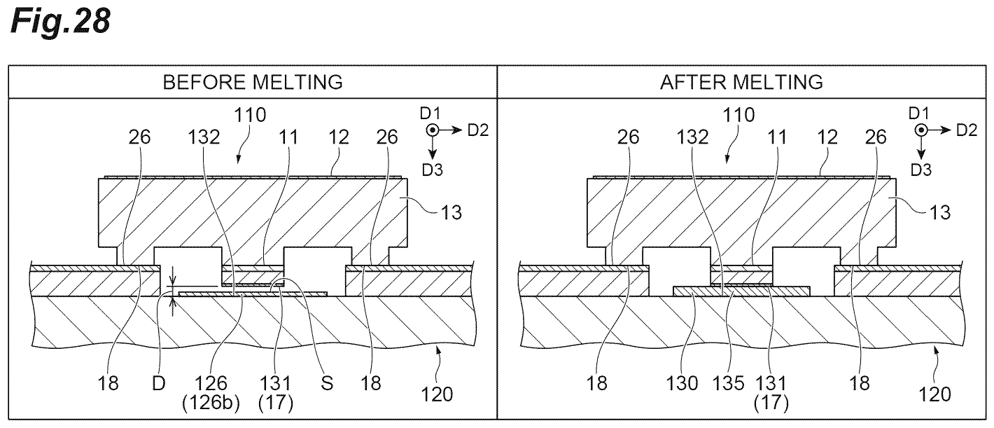

FIG. 28 shows a cross-sectional view of the first semiconductor element 110 and the second semiconductor element 120 when cut along a plane extending in the second direction D2 and the third direction D3, showing the state before and after the first bonding agent layer 126 and the second bonding agent layer 127 are melted. As shown in FIGS. 26, 27, and 28, the melted first portion 127b and the melted second portion 127c flow into the second portion 126c, and the melted third portion 127d flows into the third portion 126d and the first portion 126b.

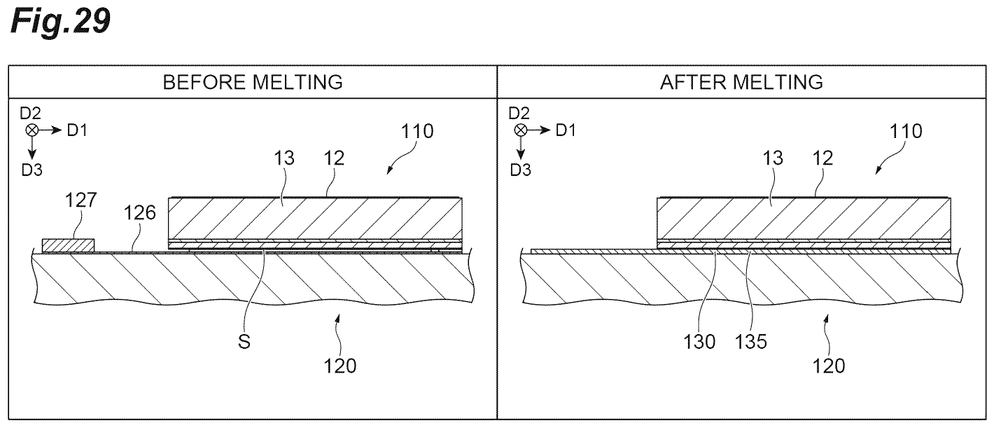

FIG. 29 shows a cross section of the first semiconductor element 110 and the second semiconductor element 120 when cut along a plane extending in the first direction D1 and the third direction D3, showing the state before and after the first bonding agent layer 126 and the second bonding agent layer 127 are melted. As shown in FIGS. 27, 28, and 29, the thickness T1 of the first bonding agent layer 126 is set to a thickness such that it does not contact the electrode 17 of the first semiconductor element 110 when the second bonding surface 26 of the second semiconductor element 120 is bonded to the first bonding surface 18 of the first semiconductor element 110.

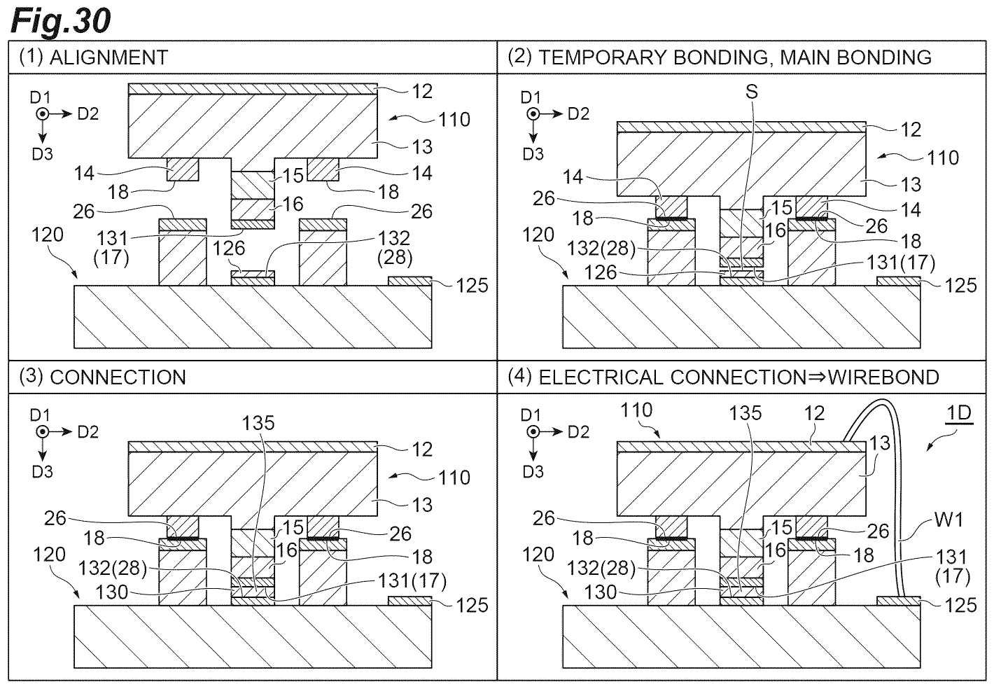

The thickness T2 of the second bonding agent layer 127 is set to a height such that the bonding agent layer 130 contacts the third bonding surface 131 when the first bonding agent layer 126 and the second bonding agent layer 127 are melted. The third bonding surface 131 is parallel to the first bonding surface 18. The third bonding surface 131 is, for example, the above-described electrode 17. The second semiconductor element 120 has a fourth bonding surface 132 facing the third bonding surface 131. The fourth bonding surface 132 is, for example, the electrode 28 of the second semiconductor element 120 (see FIG. 30).

For example, when the height of a gap S between the third bonding surface 131 and the fourth bonding surface 132 before the first bonding agent layer 126 and the second bonding agent layer 127 are melted is D, the sum of the thickness T1 and the thickness T2 is greater than D. As an example, D is 3 μm or more and 4 μm or less. For example, the thickness T1 is smaller than the thickness T2. For example, the thickness T1 is 0.1 μm or more and 20 μm or less, and the thickness T2 is 0.1 μm or more and 50 μm or less. As an example, the thickness T1 is 2 μm, and the thickness T2 is 5 μm.

With the first bonding agent layer 126 and the second bonding agent layer 127 melted, the optical semiconductor device ID includes a bonding agent layer 130 that bonds the third bonding surface 131 and the fourth bonding surface 132 to each other at the bonded portion 135. The area of the bonding agent layer 130, when viewed along the third direction D3, which is a direction crossing the third bonding surface 131 (crossing direction), is larger than the area of the bonded portion 135 when viewed along the third direction D3. The bonded portion 135 is an example of a second bonded portion. For example, the area of the bonding agent layer 130, when viewed along the third direction D3, is equal to or less than the area of the third bonding surface 131 or the area of the fourth bonding surface 132 when viewed along the third direction D3.

For example, the area of the third bonding surface 131, when viewed along the third direction D3, is equal to the area of the fourth bonding surface 132 when viewed along the third direction D3. The area ratio of the bonding agent layer 130 to the third bonding surface 131, when viewed along the third direction D3, is, for example, 1.1 or more and 5.0 or less.

Next, an example of the method for manufacturing the optical semiconductor device ID will be described with reference to FIGS. 29 and 30. FIG. 30 schematically illustrates the steps following the hydrophilic treatment in the method for manufacturing the optical semiconductor device ID. In the following description, explanations overlapping with the previously described method for manufacturing the optical semiconductor device 1 will be omitted as appropriate. As shown in FIGS. 29 and (1) of FIG. 30, the first bonding agent layer 126 is formed on the fourth bonding surface 132 of the second semiconductor element 120, and the second bonding agent layer 127 is formed on the first bonding agent layer 126 (the step of forming the second bonding agent layer on the first bonding agent layer). The formation of the first bonding agent layer 126 and the formation of the second bonding agent layer 127 are performed, for example, by vapor deposition.

Then, the alignment of the first semiconductor element 110 with respect to the second semiconductor element 120 is performed. At this time, the first bonding surface 18 of the first semiconductor element 110 and the second bonding surface 26 of the second semiconductor element 120 are aligned while facing each other and spaced apart from each other. As shown in (2) of FIG. 30, the first semiconductor element 110 is moved in the third direction D3 to bring the first bonding surface 18 into contact with the second bonding surface 26, thereby performing a temporary bonding of the first semiconductor element 110 to the second semiconductor element 120. After the temporary bonding, the first semiconductor element 110 and the second semiconductor element 120 are heated to perform main bonding of the first bonding surface 18 and the second bonding surface 26 to each other. The methods of temporary bonding and main bonding in the method for manufacturing the optical semiconductor device ID are similar to those in the method for manufacturing the previously described optical semiconductor device 1.

As shown in FIGS. 29 and (3) of FIG. 30, the first bonding agent layer 126 and the second bonding agent layer 127 are heated to melt the first bonding agent layer 126 and the second bonding agent layer 127. Then, the third bonding surface 131 and the fourth bonding surface 132 are bonded to each other by the bonding agent layer 130, which is the melted first bonding agent layer 126 and the melted second bonding agent layer 127 (the step of bonding them to each other). The heating of the first bonding agent layer 126 and the second bonding agent layer 127 is performed, for example, by reflow. However, the heating of the first bonding agent layer 126 and the second bonding agent layer 127 may also be performed by a heater, and the method of heating the first bonding agent layer 126 and the second bonding agent layer 127 is not particularly limited.

The heating of the first bonding agent layer 126 and the second bonding agent layer 127 is performed, for example, after the above-described main bonding. The heating of the first bonding agent layer 126 and the second bonding agent layer 127 may be carried out after cooling to room temperature following the main bonding, or it may be carried out without cooling to room temperature after the main bonding. The heating temperature of the first bonding agent layer 126 and the second bonding agent layer 127 is set higher than the above-described second temperature during the main bonding. The heating temperature of the first bonding agent layer 126 and the second bonding agent layer 127 is set to a temperature at which the first bonding agent layer 126 and the second bonding agent layer 127 are melted. The heating temperature is set higher than the melting point of a single metal or alloy contained in the first bonding agent layer 126 and the second bonding agent layer 127, for example. If the electrical bonding agent 32 is solder, the heating temperature is set to at least the melting point of the solder. The third temperature is, for example, 120° C. or more and 350° C. or less (an example being 280° C.). The heating time for the first bonding agent layer 126 and the second bonding agent layer 127 is, for example, 1 second or more and 300 seconds or less. As described above, when the first bonding agent layer 126 and the second bonding agent layer 127 are heated, they melt, and the bonding agent layer 130 fills the gap S.

As a result, the third bonding surface 131 and the fourth bonding surface 132 are bonded to each other through the bonding agent layer 130. After the third bonding surface 131 and the fourth bonding surface 132 are bonded to each other through the bonding agent layer 130, as shown in (4) of FIG. 30, the electrode 12 of the first semiconductor element 110 is connected to the electrode 125 of the second semiconductor element 120 through a bonding wire W1. After the first semiconductor element 110 is electrically connected to the second semiconductor element 120 as described above, a series of steps of the method for manufacturing the optical semiconductor device ID is completed.

As described above, in the optical semiconductor device ID according to the sixth embodiment, the first semiconductor element 110 has a third bonding surface 131 parallel to the first bonding surface 18, and the second semiconductor element 120 has a fourth bonding surface 132 facing the third bonding surface 131. The optical semiconductor device ID further includes a bonding agent layer 130 that bonds the third bonding surface 131 and the fourth bonding surface 132 to each other at the bonded portion 135. The area of the bonding agent layer 130, when viewed along the crossing direction, which is a direction crossing the third bonding surface 131, is larger than the area of the bonded portion 135 when viewed along the crossing direction. In this case, in addition to the bonding agent layer 130 being filled between the third bonding surface 131 and the fourth bonding surface 132 at the bonded portion 135, since the area of the bonding agent layer 130 is larger than the bonded portion 135, the third bonding surface 131 can be reliably bonded to the fourth bonding surface 132. For example, the third bonding surface 131 and the fourth bonding surface 132 can be uniformly bonded at the bonded portion 135. This reduces the stress generated in the in-plane directions parallel to the first direction D1 and the second direction D2 due to uneven bonding, and reduces the misalignment when bonding the electrode 17 of the first semiconductor element 110 and the electrode 28 of the second semiconductor element 120 to each other.

The method for manufacturing the optical semiconductor device ID includes a step of forming a first bonding agent layer 126 formed of an electrical bonding agent on the fourth bonding surface 132 and forming a second bonding agent layer 127 formed of an electrical bonding agent on the first bonding agent layer 126 before the alignment step. This manufacturing method includes a step of heating to melt the first bonding agent layer 126 and the second bonding agent layer 127, and bonding the third bonding surface 131 and the fourth bonding surface 132 to each other by the bonding agent layer 130, which is formed of the melted first bonding agent layer 126 and the melted second bonding agent layer 127.

Since the melted bonding agent layer 130 is filled between the third bonding surface 131 and the fourth bonding surface 132, the first semiconductor element 110 and the second semiconductor element 120 can be connected with minimal misalignment. Additionally, the heat generated by the first semiconductor element 110 can be efficiently dissipated to the second semiconductor element 120 through the bonding agent layer 130, thereby stabilizing the operation of the first semiconductor element 110.

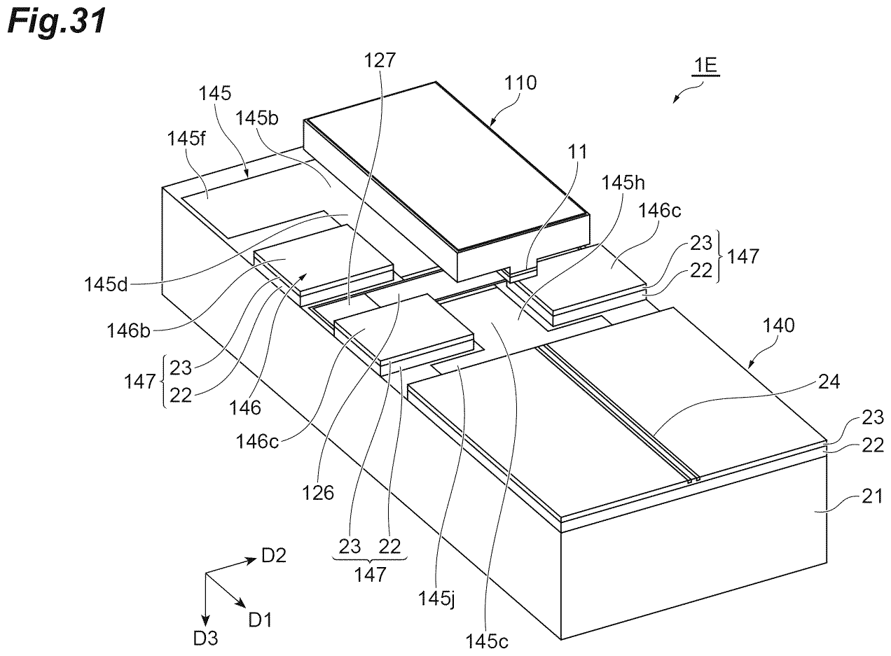

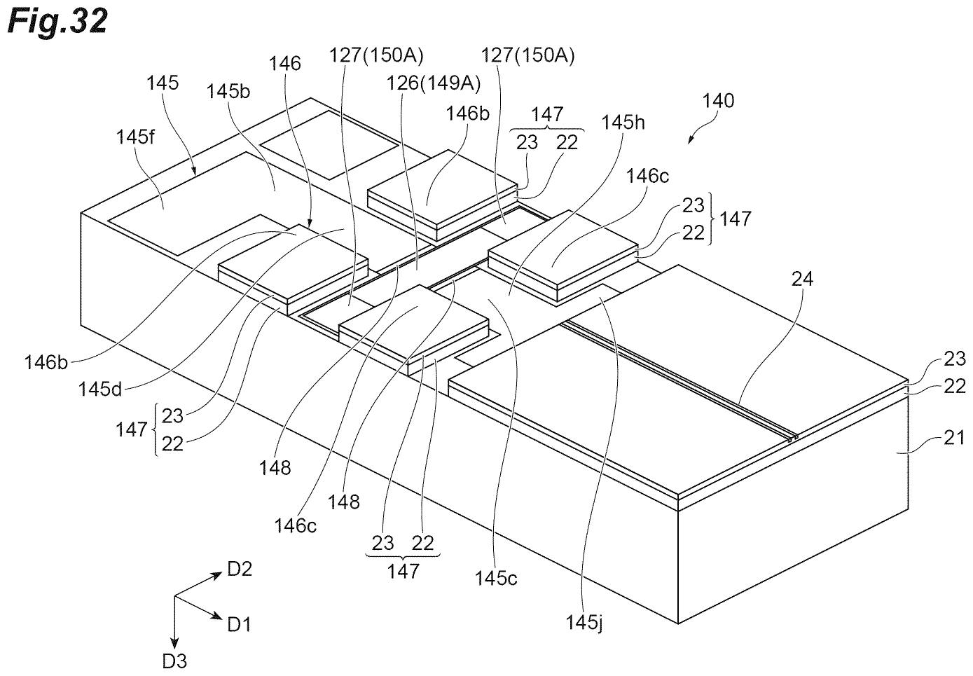

Next, the optical semiconductor device 1E according to a seventh embodiment will be described. FIG. 31 is a perspective view showing the optical semiconductor device 1E. FIG. 32 is a perspective view showing the second semiconductor element 140 of the optical semiconductor device 1E. As shown in FIGS. 31 and 32, the optical semiconductor device 1E includes a first semiconductor element 110 and a second semiconductor element 140. The second semiconductor element 140 differs from the above-mentioned second semiconductor element 120 in that it has a second bonding surface 146 different from the second bonding surface 26, and a support portion 147 different from the support portion 27. For example, the four support portions 147 are arranged in a square-like rectangular shape.

The second bonding surface 146 has a first small bonding surface 146b and a second small bonding surface 146c that are spaced apart from each other along the first direction D1, which is parallel to the second bonding surface 146. The second bonding surface 146 has two first small bonding surfaces 146b, which are aligned along the second direction D2. The second bonding surface 146 also has two second small bonding surfaces 146c, which are aligned along the second direction D2. In the plan view of the second semiconductor element 140, the two first small bonding surfaces 146b and the two second small bonding surfaces 146c are arranged in a rectangular shape.

The second semiconductor element 140 has an electrode 145. The electrodes 145 include a first electrode 145b extending in the direction opposite to the first direction D1 from between the two first small bonding surfaces 146b aligned along the second direction D2, and a second electrode 145c extending in the first direction D1 from between the two second small bonding surfaces 146c aligned along the second direction D2. The first electrode 145b includes a first portion 145d extending along the first direction D1 between the two first small bonding surfaces 146b, and a second portion 145f extending in the direction opposite to the second direction D2 from the end of the first portion 145d in the direction opposite to the first direction D1. The second electrode 145c includes a first portion 145h extending along the first direction D1 between the two second small bonding surfaces 146c, and a second portion 145j extending along the second direction D2 at the end of the first portion 145h in the first direction D1. The second portion 145j protrudes from the end of the second portion 145j in the first direction D1 in both the second direction D2 and the direction opposite to the second direction D2.

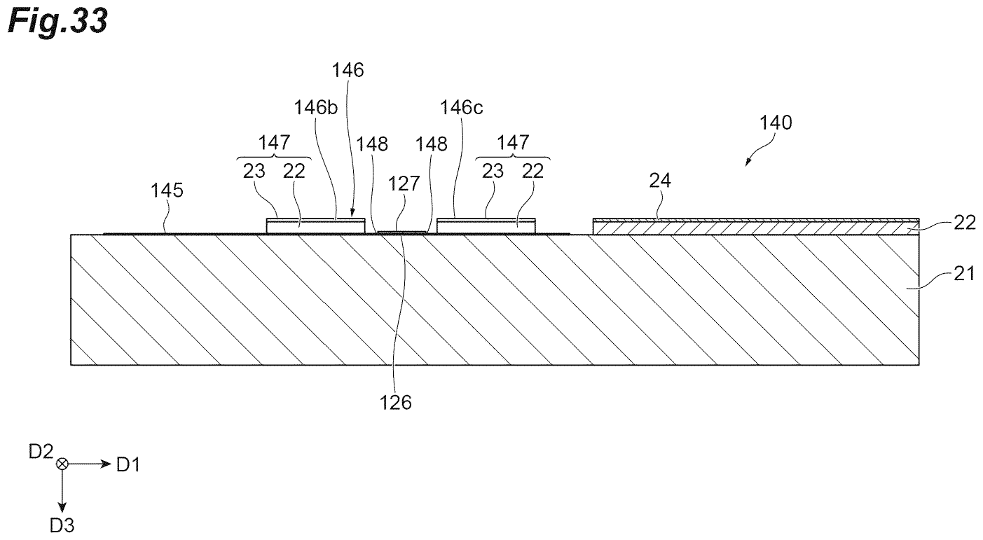

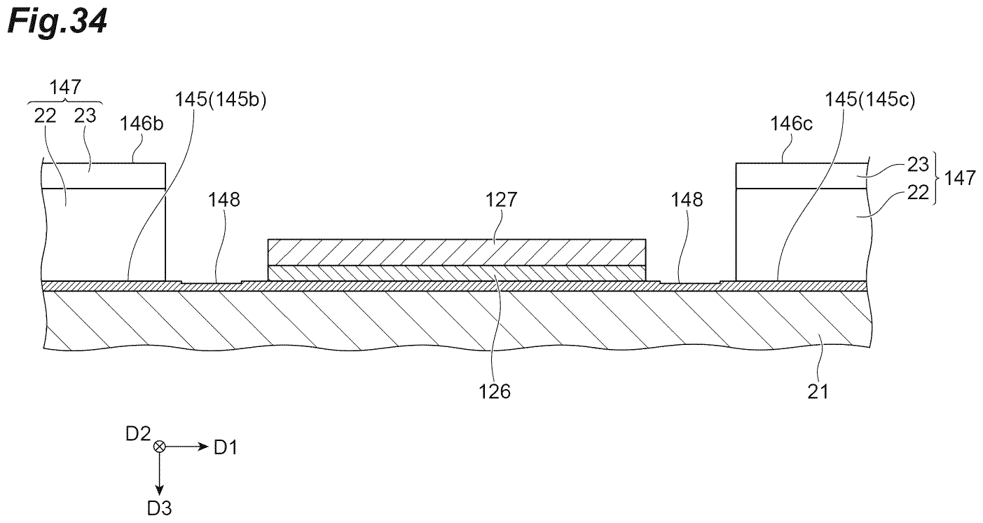

The second semiconductor element 140 has a first bonding agent layer 126 formed of an electrical bonding agent and a second bonding agent layer 127 formed on the first bonding agent layer 126 and formed of an electrical bonding agent, before the first semiconductor element 110 is bonded to the second semiconductor element 140. FIG. 33 is a cross-sectional view of the second semiconductor element 140 when cut along a plane extending in the first direction D1 and the third direction D3. FIG. 34 is an enlarged view of the portion between the first small bonding surface 146b and the second small bonding surface 146c in the cross-sectional view of FIG. 33. As shown in FIGS. 32, 33, and 34, the second semiconductor element 140 has a flow stopper 148 located between the first and second bonding agent layers 126, 127 and the electrode 145 in the first direction D1.

The flow stopper 148 is formed, for example, by etching. The flow stopper 148 prevents the molten solder (the first bonding agent layer 126 and the second bonding agent layer 127) from flowing into the electrode 145. The material of the flow stopper 148 is, for example, the same as the material of the above-mentioned flow stopper 128. The flow stopper 148 is respectively formed at the boundary between the first bonding agent layer 126 and the first electrode 145b, and at the boundary between the first bonding agent layer 126 and the second electrode 145c. The flow stopper 148 extends along the second direction D2. The second semiconductor element 140 has two flow stoppers 148, which are aligned along the first direction D1.

The second semiconductor element 140 has a first bonding agent layer region 149A, where only the first bonding agent layer 126 is formed, and a second bonding agent layer region 150A, where the second bonding agent layer 127 is formed on the first bonding agent layer 126, before the first semiconductor element 110 is bonded to the second semiconductor element 140. For example, the second semiconductor element 140 has one first bonding agent layer region 149A and two second bonding agent layer regions 150A. The first bonding agent layer region 149A extends along the second direction D2 between the first small bonding surface 146b and the second small bonding surface 146c. The second bonding agent layer regions 150A are respectively formed at the ends of the first bonding agent layer region 149A in the second direction D2 and in the direction opposite to the second direction D2. The flow stoppers 148 are respectively formed at part of the first bonding agent layer region 149A in the first direction D1 and in the direction opposite to the first direction D1.

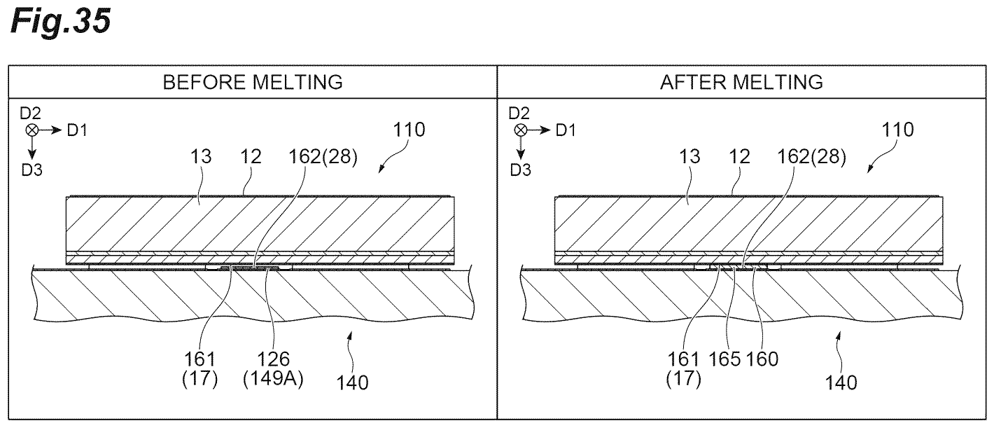

FIG. 35 shows a cross-sectional view of the first semiconductor element 110 and the second semiconductor element 140 when cut along a plane extending in the first direction D1 and the third direction D3, showing the state before and after the first bonding agent layer 126 and the second bonding agent layer 127 are melted. As shown in FIGS. 32 and 35, the second bonding agent layer 127, which has been heated to melt, flows towards the center in the second direction D2 from each of the second direction D2 and the direction opposite to the second direction D2 of the first bonding agent layer 126 . . .

With the first bonding agent layer 126 and the second bonding agent layer 127 are melted, the optical semiconductor device 1E includes a bonding agent layer 160 that bonds a third bonding surface 161 and a fourth bonding surface 162 to each other. The third bonding surface 161 is, for example, a part of the above-described electrode 17. More specifically, the third bonding surface 161 is an intermediate portion of the electrode 17 in the first direction D1, and it is the portion of the electrode 17 that faces the first bonding agent layer 126 (first bonding agent layer region 149A) along the third direction D3. The fourth bonding surface 162 is, for example, the electrode 28 of the second semiconductor element 140.

The bonding agent layer 160 is formed of the first bonding agent layer 126 and the second bonding agent layer 127, which have melted and mixed together. The volume of the bonding agent layer 160 is the sum of the volume of the first bonding agent layer region 149A and the volume of the second bonding agent layer region 150A. The area of the bonding agent layer 160, when viewed along the third direction D3, is larger than the area of the bonded portion 165 when viewed along the third direction D3. The bonded portion 165 is an example of the second bonded portion. For example, the area of the bonding agent layer 160, when viewed along the third direction D3, is equal to or less than the area of the fourth bonding surface 162 when viewed along the third direction D3.

For example, the area of the third bonding surface 161, when viewed along the third direction D3, is equal to the area of the fourth bonding surface 162 when viewed along the third direction D3. The area ratio of the bonding agent layer 160 to the third bonding surface 161, when viewed along the third direction D3, is, for example, 1.1 or more and 5.0 or less.

As described above, in the optical semiconductor device 1E according to the seventh embodiment, the second bonding surface 146 has the first small bonding surface 146b and the second small bonding surface 146c that are spaced apart from each other along the first direction D1, which is a direction parallel to the second bonding surface 146. The first semiconductor element 110 has the third bonding surface 161 that is parallel to the first bonding surface 18 and extends in the second direction D2, which is a direction crossing the first direction D1, between the first small bonding surface 146b and the second small bonding surface 146c. The second semiconductor element 140 has the fourth bonding surface 162 that faces the third bonding surface 161 and extends in the first direction D1. The optical semiconductor device 1E further includes the bonding agent layer 160 that bonds the third bonding surface 161 and the fourth bonding surface 162 to each other. In this case, the third bonding surface 161 can be strongly bonded to the fourth bonding surface 162, thereby reducing misalignment when bonding the electrode 17 of the first semiconductor element 110 and the electrode 28 of the second semiconductor element 140 to each other.

In the optical semiconductor device 1E, similar to the above-described optical semiconductor device ID, the third bonding surface 161 is bonded to the fourth bonding surface 162 by the bonding agent layer 160, which is, for example, solder. In the optical semiconductor device 1E, the third bonding surface 161 is a part of the electrode 17, and a part of the electrode 17 is bonded to the electrode 28 by solder. Therefore, compared to bonding the entire electrode 17 to the electrode 28, the bonding strength of the third bonding surface 161 to the fourth bonding surface 162 can be reduced, thereby minimizing the impact of the solder bonding on the hydrophilic bonding. Furthermore, by bonding the third bonding surface 161, which is an intermediate portion of the electrode 17 in the first direction D1, to the fourth bonding surface 162, it is possible to prevent the first semiconductor element 110 from tilting due to an imbalance in the solder.

Various embodiments and various modification examples of the optical semiconductor device and the method for manufacturing the optical semiconductor device according to the present disclosure have been described above. However, the present disclosure is not limited to the above-described embodiments or modification examples, and may be further modified within the scope described in the claims. That is, the configuration, shape, size, material, number, and arrangement of each portion of the optical semiconductor device according to the present disclosure and the content and order of the steps of the method for manufacturing the optical semiconductor device can be changed as appropriate within the scope of the aforementioned gist.

For example, in the above-described embodiments, an example has been described in which a hydrophilic treatment is performed on both the first bonding surface 18 and the second bonding surface 26. However, the hydrophilic treatment on the second bonding surface 26 may be omitted. In the above-described embodiments and modification examples, various examples of the first bonding surface and the second bonding surface have been described. The material of the first bonding surface may be indium phosphide (InP), indium gallium arsenide (InGaAs), gallium indium arsenide phosphide (GaInAsP), aluminum gallium indium arsenide (AlGaInAs), silicon dioxide (SiO₂), or silicon nitride (SiN). The material of the second bonding surface may be silicon (Si), silicon dioxide (SiO₂), or silicon nitride (SiN). In this manner, the material of the first bonding surface and the material of the second bonding surface can be changed as appropriate.

Various optical semiconductor devices according to the first to seventh embodiments and the first to fifth modifications have been described above. The optical semiconductor device according to the present disclosure may be configured by elements selected from the above-mentioned first to seventh embodiments and the first to fifth modifications. Furthermore, the combination of the first semiconductor element and the second semiconductor element in the optical semiconductor device can be appropriately modified. For example, the optical semiconductor device may include any of the first semiconductor elements 10, 10A, 10B, 10C, 40, 40A, 60, 80, 110 bonded to any of the second semiconductor elements 120, 140. In other words, the combination of the first semiconductor elements 10, 10A, 10B, 10C, 40, 40A, 60, 80, 110 with the second semiconductor elements 20, 50, 70, 90, 120, 140 can be appropriately modified.

What is claimed is:

1. An optical semiconductor device, comprising:
a first semiconductor element having a first bonding surface and an end surface which crosses the first bonding surface and from which an optical signal is emitted; and
a second semiconductor element having a second bonding surface facing the first bonding surface and an optical waveguide which extends in a direction parallel to the second bonding surface and through which the optical signal is transmitted,
wherein the first bonding surface and the second bonding surface are bonded to each other in a hydrophilic manner, and
the end surface of the first semiconductor element and the optical waveguide of the second semiconductor element are optically coupled to each other.

2. The optical semiconductor device according to claim 1,
wherein an oxide film is formed at a bonded portion that is a portion where the first bonding surface and the second bonding surface are bonded to each other in a hydrophilic manner.

3. The optical semiconductor device according to claim 1,
wherein the first semiconductor element has a third bonding surface parallel to the first bonding surface,
the second semiconductor element has a fourth bonding surface facing the third bonding surface,
the optical semiconductor device further includes a bonding agent layer which bonds the third bonding surface and the fourth bonding surface to each other at a bonded portion, and
an area of the bonding agent layer when viewed along a crossing direction that is a direction crossing the third bonding surface is larger than an area of the bonded portion when viewed along the crossing direction.

4. The optical semiconductor device according to claim 1, wherein the second bonding surface has a first small bonding surface and a second small bonding surface spaced apart from each other along a first direction that is a direction parallel to the second bonding surface,
the first semiconductor element has a third bonding surface being parallel to the first bonding surface, and extending in a second direction that is a direction crossing the first direction, the third bonding surface provided between the first small bonding surface and the second small bonding surface,
the second semiconductor element has a fourth bonding surface facing the third bonding surface and extending in the first direction, and
the optical semiconductor device further includes a bonding agent layer bonding the third bonding surface and the fourth bonding surface to each other at a bonded portion.

5. A method for manufacturing an optical semiconductor device, comprising:
a step of making a first bonding surface of a first semiconductor element hydrophilic;
a step of aligning an end surface of the first semiconductor element, from which an optical signal is emitted, and an optical waveguide of a second semiconductor element, through which the optical signal is transmitted, so as to be optically coupled to each other by making the first bonding surface face a second bonding surface of the second semiconductor element with the first bonding surface spaced apart from the second bonding surface;
a step of temporarily bonding the first semiconductor element and the second semiconductor element to each other by bringing the first bonding surface into contact with the second bonding surface at a first temperature and pressing at least one of the first semiconductor element and the second semiconductor element; and
a step of heating the first semiconductor element and the second semiconductor element after the temporary bonding step for main bonding between the first bonding surface and the second bonding surface at a second temperature higher than the first temperature.

6. The method for manufacturing an optical semiconductor device according to claim 5,
wherein, in the hydrophilizing step, the first bonding surface is made hydrophilic by irradiating the first bonding surface with ultraviolet light in an air exposure environment.

7. The method for manufacturing an optical semiconductor device according to claim 5,
wherein, in the hydrophilizing step, the first bonding surface is made hydrophilic by exposing the first bonding surface to oxygen plasma in a vacuum environment.

8. The method for manufacturing an optical semiconductor device according to claim 5,
wherein, in the hydrophilizing step, the first bonding surface is made hydrophilic by exposing the first bonding surface to nitrogen plasma in a vacuum environment.

9. The method for manufacturing an optical semiconductor device according to claim 5,
wherein a strength of a bonded portion, which is a portion where the first bonding surface and the second bonding surface are bonded to each other, after the temporary bonding step is 5 MPa or more.

10. The method for manufacturing an optical semiconductor device according to claim 5,
wherein a distance between the first bonding surface and the second bonding surface when performing the alignment step is 1 μm or more and less than 100 μm.

11. The method for manufacturing an optical semiconductor device according to claim 5,
wherein the first temperature is 20° C. or more and 40° C. or less, and
the second temperature is 100° C. or more and 300° C. or less.

12. The method for manufacturing an optical semiconductor device according to claim 5,
wherein the first semiconductor element has a third bonding surface parallel to the first bonding surface,
the second semiconductor element has a fourth bonding surface facing the third bonding surface,
the method comprises, prior to the alignment step, a step of forming a first bonding agent layer formed of an electrical bonding agent on the fourth bonding surface, and forming a second bonding agent layer formed of the electrical bonding agent on the first bonding agent layer, and
the method comprises, a step of melting the first bonding agent layer and the second bonding agent layer through heating, and bonding the third bonding surface and the fourth bonding surface to each other by a bonding agent layer being the melted first bonding agent layer and the melted second bonding agent layer.
